(19) United States
(12) Patent Application Publication
(10) Pub. No.: US 2026/0074726 A1
(43) Pub. Date: Mar. 12, 2026

(54) SYSTEMS AND METHODS FOR FILTERING RADIO FREQUENCY SIGNALS

(71) Applicant: Metamagnetics Inc., Marlborough, MA (US)

(72) Inventors: Scott M. Gillette, Norfolk, MA (US); David Audette, Marlborough, MA (US); Reena Dahle, Marlborough, MA (US); Randy Camasso, Methuen, MA (US)

(73) Assignee: Metamagnetics Inc., Marlborough, MA (US)

(21) Appl. No.: 18/883,342

(22) Filed: Sep. 12, 2024

(51) Int. Cl. H04B 1/10; H03F 3/19

(52) U.S. Cl. CPC H04B 1/1036; H03F 3/19; H03F 2200/451

(57) ABSTRACT

Embodiments of the present disclosure relate to RF filter systems and methods. In some embodiments, an RF filter system includes a tuning signal injection circuitry, a tuning signal cancellation circuitry, and two FSLs. The RF filter system may receive one or more first RF signals that may include one or more signals of interest (SOIs) and one or more interfering signals. The RF filter system may receive one or more second RF signals that may include one or more tuning signals. The RF filter system may output one or more RF signals containing the one or more SOIs and attenuated versions of the interfering signals, without including the one or more tuning signals.

### BACKGROUND

Tunable notch filter banks are utilized in radio frequency (RF) receive systems to suppress unwanted interfering signals in a receive system signal path (e.g., a receiver “front-end” or a “receive chain”). These interfering signals typically exist in a frequency spectrum of interest (e.g., within a receive frequency band of the receive system), and have a power level which interferes with the ability of a receive system to receive and/or process signals of interest, such as by degrading sensitivity of an RF receive chain to signals of interest (e.g., saturate, overload, disrupt, and/or damage one or more components of a receive system such as one or more components of a receive chain or receiver front-end).

Such interfering signals may be intentional, such as jamming signals or attack signals (i.e., one or more signals in the microwave or RF frequency bands having power levels selected to interfere with the ability of a receive system to receive and/or process signals of interest). Such interfering signals may also be unintentional, such as co-site interference signals or self, “friendly,” or neutral electromagnetic interference (EMI) (e.g., signal fratricide). By filtering these interfering signals from the spectrum of interest, an RF receiver may operate as intended, without being partially or fully desensitized to signals of interest.

To reduce, and ideally minimize, the impact of interfering systems, receive systems may sometimes include tunable notch filter banks. Current tunable notch filter banks have filter characteristics (sometimes referred to as “filter regions” or “notches”) which accomplish filtering at frequencies or frequency bands that can be independently controlled. Some current filter devices use multiple independently-tunable notch filters, notch filter banks, or switched filter banks. These devices require use of sense-and-control feedback loops to determine where high power interfering signals are in the RF spectrum, and generate tuning commands to move one or more notches to suppress the interfering signals. Such devices consume a significant amount of power and are relatively slow to respond to interfering signals. Additionally, the number of notches supported by such filter devices may be a function of the number of devices used, and so a large number of devices may be needed to provide a large number of notches.

A frequency selective limiter (FSL) is a nonlinear passive device that attenuates RF signals provided to an input thereof having a power level which is above a predetermined threshold power level. RF signals having a power level below the predetermined threshold power level, on the other hand, propagate from the input of the FSL to the output of the FSL substantially unattenuated.

One feature of an FSL is the frequency selective nature of limiting high-power signals. More specifically, an FSL has a characteristic such that low power signals (e.g., signals having a power level below a threshold power level) close in frequency to high-power signals (e.g., signals having a power level equal to or above a threshold power level) are substantially unaffected (e.g., the FSL does not substantially attenuate such signals).

A typical implementation of an FSL includes a stripline transmission structure provided from two layers of dielectric material disposed about a strip conductor, with the strip conductor having a fixed length and a fixed width along the length of the FSL. Such structures can be relatively simple to fabricate and provide adequate magnetic fields to realize a critical power level of approximately 0 decibel milliwatts (dBm) when using a single crystal material.

Ferrite-based FSLs have the ability to automatically and selectively suppress signals that exceed a designated power threshold while simultaneously allowing for signals below the threshold to pass without attenuation. This functionality can be valuable in receiver front ends as a protection component, because it can allow lower power signals to be detected while higher power signals that could otherwise saturate, overload, disrupt, and/or damage the receiver can be simultaneously and automatically suppressed. The FSL does not need any a priori knowledge of the input spectrum, and no computerized feedback or control loop is required. The FSL's transmission response can automatically and dynamically adjust to the input spectrum based on power spectral density and can automatically generate notches in the transmission response proportional to a signal's supercriticality (e.g., how far a signal's power is above a designated power threshold level). In this way, an FSL can automatically and dynamically adapt to a changing input spectrum with exceptional speed.

### SUMMARY

Embodiments of the present disclosure relate to RF filter systems and methods. In some embodiments, an RF filter system includes tuning signal injection circuitry that receives one or more first RF signals and one or more second RF signals. The one or more first RF signals may include, for example, one or more signals of interest (SOI). The one or more first RF signals may also include one or more higher power signals, such as interfering signals. The one or more second RF signals may include one or more tuning signals configured to generate one or more notches in the transmission response of the RF filter system. The RF filter system may also include first and second frequency selective limiters (FSLs). The first and second FSLs may cause the RF filter system to have a transmission response with one or more notches corresponding to the one or more second RF signals, and may attenuate one or more higher power signals output from the tuning signal injection circuitry. The RF filter system may also include tuning signal cancellation circuitry that receives RF signals from the first FSL and the second FSL and that outputs one or more RF signals. The output one or more RF signals may include the one or more signals of interest. The output one or more RF signals may not include the one or more tuning signals. Thus, the systems and methods disclosed herein may allow for injecting one or more tuning signals to generate notches in an RF filter system's transmission response to attenuate unwanted signals, and for removal of the tuning signals such that the tuning signals are not in the RF filter system's output.

In accordance with some embodiments, there is provided a radio frequency (RF) filter system. The RF filter system comprises tuning signal injection circuitry with a first input configured to receive one or more first RF signals and a second input configured to receive one or more second RF signals. The RF filter system further comprises a first frequency selective limiter (FSL) coupled to a first output of the tuning signal injection circuitry.

In some embodiments, the RF filter system further comprises a second FSL coupled to a second output of the tuning signal injection circuitry, and tuning signal cancellation circuitry coupled to an output of the first FSL and to an output of the second FSL.

In further embodiments, the first FSL is configured to attenuate one or more RF signals received from the first output of the tuning signal injection circuitry and having one or more frequencies corresponding to one or more notches in a transmission response of the first FSL.

In still further embodiments, the second FSL is configured to attenuate one or more RF signals received from the second output of the tuning signal injection circuitry and having one or more frequencies corresponding to one or more notches in a transmission response of the second FSL.

In some embodiments, the transmission response of the first FSL and the transmission response of the second FSL are the same.

In further embodiments, the one or more frequencies of the one or more attenuated RF signals correspond to one or more frequencies of the one or more second FSL signals.

In still further embodiments, the first FSL and the second FSL comprise absorptive FSLs.

In some embodiments, the first FSL and the second FSL comprise ferrite-based FSLs.

In further embodiments, the first FSL and the second FSL comprise magnetostatic surface wave (MSSW) FSLs.

In still further embodiments, the tuning signal injection circuitry comprises a ninety degree hybrid coupler.

In some embodiments, the tuning signal cancellation circuitry comprises a ninety degree hybrid coupler.

In further embodiments, the tuning signal injection circuitry comprises a ninety degree hybrid coupler and the tuning signal cancellation circuitry comprises a ninety degree hybrid coupler.

In still further embodiments, the one or more first RF signals comprises a signal of interest and the one or more second RF signals comprises a signal tuned to a first frequency to cause the system to attenuate any of the one or more first RF signals at the first frequency.

In some embodiments, the one or more first RF signals comprises a signal of interest and an interfering signal, and the RF filter system is configured to output third RF signals including the signal of interest and an attenuated version of the interfering signal.

In further embodiments, the tuning signal injection circuitry comprises a first output configured to output one or more third RF signals that are a combination of the first one or more RF signals and the second one or more RF signals, where the signals combined based on the second one or more RF signals are phase-shifted by ninety degrees relative to the signals combined based on the first one or more RF signals.

In further embodiments, the tuning signal injection circuitry comprises a second output configured to output one or more fourth RF signals that are a combination of the second one or more RF signals and the first one or more RF signals, wherein the signals combined based on the first one or more RF signals are phase-shifted by ninety degrees relative to the signals combined based on the second one or more RF signals.

In still further embodiments, the first FSL receives the one or more third RF signals, attenuates one or more of the one or more third RF signals having one or more frequencies corresponding to one or more notches in a transmission response of the first FSL, and outputs the attenuated one or more of the one or more third RF signals and the remaining RF signals of the one or more third RF signals as one or more fifth RF signals. The second FSL receives the one or more fourth RF signals, attenuates one or more of the one or more fourth RF signals having one or more frequencies corresponding to one or more notches in a transmission response of the second FSL, and outputs the attenuated one or more of the one or more fourth RF signals and the remaining RF signals of the one or more fourth RF signals as one or more sixth RF signals.

In some embodiments, the tuning signal cancellation circuitry receives the one or more fifth RF signals at a first input and the one or more sixth RF signals at a second input.

In further embodiments, the tuning signal cancellation circuitry outputs one or more seventh RF signals that are a combination of the one or more sixth RF signals and the one or more fifth RF signals, whereby the combination of the one or more sixth RF signals and the one or more fifth RF signals results in cancellation of components of the one or more second RF signals, such that the one or more seventh RF signals do not include the components of the one or more second RF signals.

In still further embodiments, the one or more seventh RF signals comprise only components of the one or more first RF signals.

In some embodiments, the tuning signal cancellation circuitry outputs one or more eighth RF signals that are a combination of the one or more fifth RF signals and the one or more sixth RF signals, whereby the combination of the one or more fifth RF signals and the one or more sixth RF signals results in cancellation of components of the one or more first RF signals, such that the one or more eighth RF signals do not include the components of the one or more first RF signals.

In further embodiments, the output of the tuning signal cancellation circuitry is terminated in a load.

In still further embodiments, the first FSL is coupled to the tuning signal injection circuitry over a first interconnect and is coupled to the tuning signal cancellation circuitry over a second interconnect. The second FSL is coupled to the tuning signal injection circuitry over a third interconnect and is coupled to the tuning signal cancellation circuitry over a fourth interconnect.

In some embodiments, the tuning signal injection circuitry, first FSL, second FSL, tuning signal cancellation circuitry, first interconnect, second interconnect, third interconnect, and fourth interconnect are matched.

In further embodiments, the RF filter system further comprises one or more phase and gain compensation components to compensate for unmatched components.

In still further embodiments, the one or more second RF signals are generated by one of a signal generator, waveform generator, arbitrary waveform generator, field-programmable gate array (FPGA), software-defined radio (SDR), RF synthesizer, antenna, or voltage-controlled oscillator (VCO).

In some embodiments, the RF filter system further comprises a third FSL coupled to the first input of the tuning signal injection circuitry.

In further embodiments, the third FSL is a reflective FSL.

In further embodiments, the third FSL is a magnetostatic surface wave (MSSW) FSL.

In still further embodiments, an input of the third FSL is coupled to a circulator.

In some embodiments, the circulator is configured to receive one or more RF signals and output the one or more RF signals to the third FSL, receive one or more of the one or more RF signals reflected from the third FSL, and output the reflected one or more RF signals.

In further embodiments, the output reflected one or more RF signals comprises the second one or more RF signals.

In still further embodiments, the RF filter system further comprises an amplifier configured to receive the output reflected one or more RF signals and to send an amplified version of the output reflected one or more RF signals as the second one or more RF signals.

In some embodiments, the third FSL has a predetermined threshold power level.

In further embodiments, the RF filter system further comprises a signal-to-noise enhancer configured to receive the output reflected one or more RF signals and to attenuate any of the output reflected one or more RF signals having a power level that is below a predetermined threshold power level of the signal-to-noise enhancer.

In still further embodiments, the third FSL has a first predetermined threshold power level and the predetermined threshold power level of the signal-to-noise enhancer is a second predetermined threshold power level, where the first predetermined threshold power level and the second predetermined threshold power level are the same.

In still further embodiments, the third FSL has a first predetermined threshold power level and the predetermined threshold power level of the signal-to-noise enhancer is a second predetermined threshold power level, where the first predetermined threshold power level and the second predetermined threshold power level are different.

In some embodiments, the RF filter system further comprises an amplifier configured to receive one or more RF signals output from the signal-to-noise enhancer and to provide an amplified version of the one or more RF signals output from the signal-to-noise enhancer as the one or more second RF signals.

In further embodiments, the amplifier is a first amplifier, further comprising a second amplifier, the circulator configured to receive the one or more RF signals from the second amplifier.

In still further embodiments, the RF filter system further comprises an RF coupler configured to receive one or more RF signals, wherein the one or more first RF signals and the one or more second RF signals are based on signals output from the RF coupler.

In still further embodiments, a direct path of the RF coupler is coupled to the first input of the tuning signal injection circuitry, and a coupled path of the RF coupler is coupled to the second input of the tuning signal injection circuitry.

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principles of the concepts described herein. Like reference numerals may designate corresponding parts throughout the different views. Furthermore, embodiments are illustrated by way of example and not limitation in the figures.

FIG. 1 is an isometric view of an example magnetostatic surface wave (MSSW) filter that may be used as an FSL.

FIG. 2A is a graph of power spectral density vs. frequency of example RF signals provided to an example FSL.

FIG. 2B is a graph of insertion loss vs. frequency resultant from the RF signals of FIG. 2A being input to the example FSL.

FIG. 2C is a graph of power spectral density vs. frequency at an output of the example FSL.

FIG. 3A is a block diagram of an example RF filter system where tuning signals are injected to generate notches.

FIG. 3B is a plot of power vs. frequency of an RF filter signal output resultant from example RF signals passing through an example RF filter system with example tuning signals injected.

FIG. 4 is a block diagram of an example ninety degree) (90° hybrid coupler.

FIG. 5 is a block diagram of an example system with two ninety degree (90°) couplers coupled together.

FIG. 6A is a block diagram of an example RF filter module, consistent with embodiments of the present disclosure.

FIG. 6B is a block diagram of an example RF filter system with two couplers and two FSLs, consistent with embodiments of the present disclosure.

FIG. 6C is a block diagram of an example RF filter system consistent with embodiments of the present disclosure, with graphs of example spectra for different signals in the example RF filter system.

FIG. 6D is a graph of power vs. frequency of RF signals output from an example RF filter system consistent with embodiments of the present disclosure in response to example tuning signals provided thereto.

FIG. 7 is a graph of insertion loss vs. frequency of an example RF filter system in response to example tuning signals provided thereto.

FIG. 8A is a block diagram of an example RF filter system that includes a reflective FSL, a circulator, and an amplifier, consistent with embodiments of the present disclosure.

FIG. 8B is a block diagram of an example RF filter system that includes a reflective FSL, a circulator, and an amplifier, consistent with embodiments of the present disclosure, with graphs of example spectra for different signals in the example RF filter system.

FIG. 9 is a block diagram of an example RF filter system that includes a reflective FSL, a circulator, a signal-to-noise enhancer, and an amplifier, consistent with embodiments of the present disclosure.

FIG. 10 is a block diagram of an example RF filter system that includes a reflective FSL, a circulator, a first amplifier, and a second amplifier, consistent with embodiments of the present disclosure.

FIG. 11 is a block diagram of an example RF filter system that includes an RF coupler, an RF conditioning block, and an amplifier, consistent with embodiments of the present disclosure.

FIG. 12 is a block diagram of an example RF filter module that includes additional RF components, consistent with embodiments of the present disclosure.

FIG. 13 is a flow diagram of an example process for filtering RF signals, consistent with embodiments of the present disclosure.

### DETAILED DESCRIPTION

Reference will now be made in detail to the embodiments of the disclosure, certain examples of which are illustrated in the accompanying drawings.

In the following description, numerous specific details are set forth regarding the systems and methods of the disclosed subject matter, and the environment in which such systems and methods operate, to provide a thorough understanding of the disclosed subject matter. After reading the descriptions provided herein, it will be apparent to one skilled in the art, however, that the disclosed subject matter may be practiced without such specific details. It will also be apparent to one skilled in the art that certain features, which are well known in the art, are not described in detail to avoid unnecessary complication of the description of the systems and methods described herein. In addition, it will be understood that the embodiments provided below are exemplary, and that it is contemplated that there are other systems and methods that are within the scope of the subject matter disclosed herein.

A ferrite-based frequency selective limiter (FSL) may be used to discriminate signals based on power. For example, a transmission response of a ferrite-based FSL may automatically adjust to attenuate signals with power levels equal to or above a predetermined power threshold level. The FSL may pass signals with power levels below the predetermined power threshold level linearly and with low power loss.

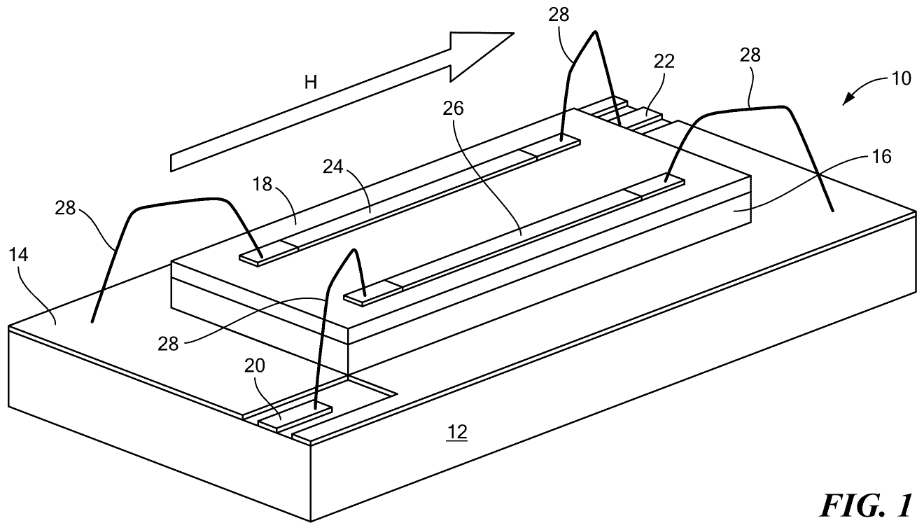

FIG. 1 shows a diagram of an example magnetostatic surface wave (MSSW) filter 10 that may be an FSL. Example MSSW filter 10 may include a substrate 12 (illustrated in FIG. 1 as a monolithic microwave integrated circuit (MMIC) having a ground plane 14 disposed on a first surface thereof). Example MSSW filter 10 may also have a Gadolinium Gallium Garnet (GGG) layer 16 disposed over ground plane 14. A person of ordinary skill in the art would appreciate that MMIC substrate 12 may comprise any dielectric, magnetic, semiconductor substrate to which the MSSW device may be mounted.

Example MSSW filter 10 may also include a layer of ferrite material 18 disposed over GGG layer 16. The layer of ferrite material may comprise yttrium iron garnet (YIG), as one example, however any ferrimagnetic material appropriate for use at microwave frequencies may be used. Other example materials include lithium ferrite, nickel-zinc ferrite, and barium ferrite.

RF transmission lines (illustrated in FIG. 1 as micro-strip transmission lines) may be disposed on the first surface of substrate 12, and may serve as ports (e.g., ports 20, 22) of the MSSW filter. The ports may be RF input and output ports. The RF transmission lines may also be provided as co-planar waveguide, microstrip, stripline, coaxial, or any other type of microwave transmission line. It should be appreciated by one of ordinary skill in the art that, depending on the type of MSSW device being designed, both reciprocal or non-reciprocal wave propagation may be supported. Also, depending on the type of MSSW device, a bias field may be used to switch the direction of non-reciprocity. Thus, in embodiments, either of ports 20 and 22 may serve as an input port or an output port.

A pair of transducers (e.g., transducers 24, 26) may be disposed over layer of ferrite material 18. A first end of each transducer may be coupled to ground plane 14 and a second end of each transducer may be coupled to one of MSSW filter ports 20, 22 (i.e., coupled to the transmission lines). In the example of FIG. 1, the ends of transducers 24, 26 are coupled to respective ones of ground plane 14 and MSSW filter ports 20, 22 via respective bond wires 28. Other techniques (including but not limited to conductive ribbons, ground vias) may of course be used to couple the ends of transducers 24, 26 to the respective ones of ground plane 14 and MSSW filter ports 20, 22.

An in-plane magnetic biasing field (H) having a direction parallel to the direction of transducers 24, 26 may be applied to MSSW filter 10 to provide a magnetic bias configuration suitable for generating magnetostatic surface waves (MSSWs). In general, the biasing field (H) may have a magnitude selected to saturate the layer of ferrite material 18 and overcome any demagnetization and/or ferrite magnetic anisotropy factors, while also providing the internal magnetic field suitable for a desired frequency range of MSSWs.

The magnetic biasing field may be embedded inside the finished device. Furthermore, the magnitude of the magnetic biasing field may be changed (e.g., graded, stepped, tapered, multiplexed) between different levels. In some embodiments, it may be desirable to only change the magnitude of the bias field. The direction of the magnitude of the bias field may need to be fixed in order to satisfy conditions for creating magnetostatic surface waves.

While one example MSSW filter 10 that may be used as an FSL has been described with reference to FIG. 1, the disclosure is not so limited. A person of ordinary skill in the art would recognize that other types of FSLs may be used in the example embodiments described herein, and the disclosure herein should be considered to encompass these other types of FSLs. For example, FSLs that utilize one or more stripline or coplanar waveguide conductors, with the conductors being surrounded on one or both sides by a ferrite, may be utilized in the example embodiments disclosed herein.

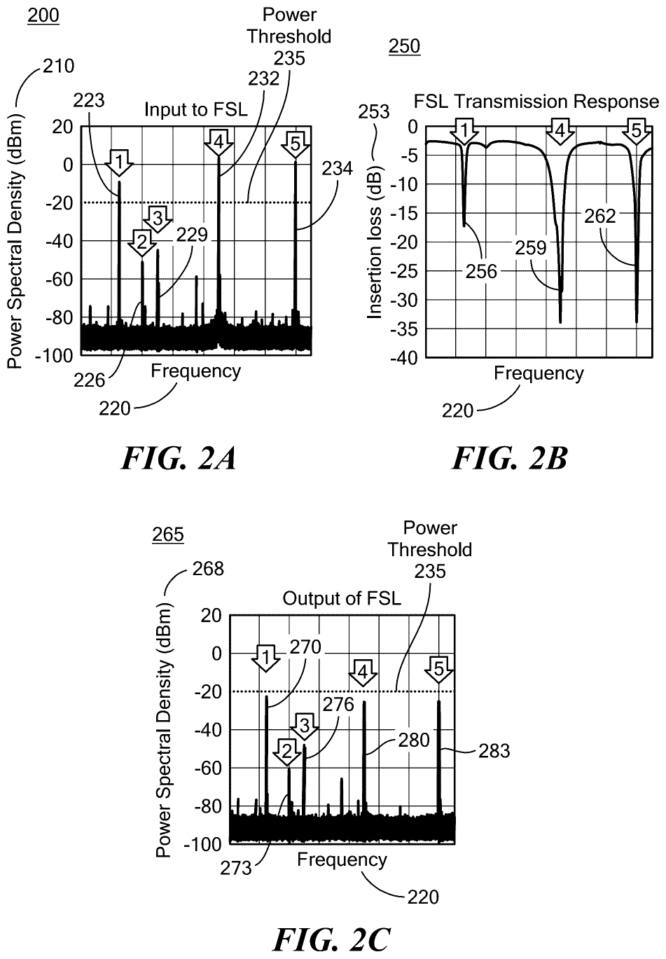

FIG. 2A shows a graph 200 of power spectral density and frequency of example RF signals input to an example FSL. Graph 200 includes a Y-axis 210 that corresponds to power in decibel-milliwatts (dBm), and an X-axis 220 that corresponds to frequency. Graph 200 shows a plot of power levels of example RF signals at different frequencies input to an FSL. 235 represents the predetermined power threshold level of the example FSL, which is approximately −20 dBm for this example FSL. In the example shown in FIG. 2A, signals 223, 232, and 234 have power levels exceeding the predetermined power level threshold, while the other signals, including signals 226 and 229, have power levels that are less than the predetermined power threshold level.

FIG. 2B shows a graph 250 of the example FSL's transmission response to the example RF signals shown in FIG. 2A. Graph 250 includes a Y-axis 253 that corresponds to insertion loss in dB, and an X-axis 220 that corresponds to frequency as discussed with respect to FIG. 2A. Graph 250 shows a plot of power levels of insertion loss of the FSL at different frequencies. As shown in graph 250, notches 256, 259, 262 are generated at frequencies corresponding to the frequencies of the signals (i.e., signals 223, 232, 234) received by the FSL that had power levels exceeding predetermined threshold power level 235. That is, notch 256 corresponds to signal 223, notch 259 corresponds to signal 232, and notch 262 corresponds to signal 234. As further shown in FIG. 2B, the depth of a notch corresponds to the amount by which the power level of a signal exceeds predetermined power level threshold 235. For example, signals 232 and 234 exceed predetermined power level threshold 235 by more than signal 223, and so notches 259 and 262 are deeper than notch 256. As also shown in FIG. 2B, signals input to the FSL that have power levels below predetermined power level 235 are passed through the FSL linearly with lower loss. For example, each of these signals passes through the FSL with approximately 3 dB of insertion loss, regardless of the signal frequency and below-threshold power level.

FIG. 2C shows a graph 265 of power spectral density and frequency of example RF signals output from an example FSL. Graph 265 includes a Y-axis 268 that corresponds to power in dBm, and an X-axis 220 that corresponds to frequency as discussed with respect to FIGS. 2A and 2B. Graph 265 shows a plot of power levels of RF signals output from the example FSL, based on the example input signals to the FSL of FIG. 2A. As shown in graph 265, the signals input to the FSL have been reduced in power by the amount of insertion loss of the FSL at certain frequencies. For the RF signals (i.e., signals 223, 232, 234) input to the FSL that had power levels exceeding predetermined threshold power level 235, their power level has been reduced by the generated notches in the FSL's transmission response, so that the power levels of the corresponding output signals are below predetermined power level threshold 235. For example, signal 223 has been reduced in power by approximately 17 dBm to approximately −25 dBm and is output as signal 270, signal 232 has been reduced in power by approximately 34 dBm to approximately −28 dBm and is output as signal 280, and signal 234 has been reduced in power by approximately 34 dBm to approximately −29 dBm, and is output as signal 283. For the RF signals (e.g., signals 226, 229) input to the FSL that had power levels below predetermined threshold power level 235, their power level has been reduced by approximately 3 dBm. For example, signal 226 has been reduced in power by approximately 3 dBm to approximately −60 dBm, and signal 229 has been reduced in power by approximately 3 dBm to approximately −50 dBm.

A characteristic of the notches generated in the transmission response of a ferrite-based FSL (e.g., MSSW filter 10 of FIG. 1) is that the notches are centered around signals with power levels equal to or above the predetermined threshold power level of the FSL. Another characteristic of the generated notches is that they have a selectivity bandwidth characteristic. For example, a bandwidth of a generated notch may depend on a power level of a signal. In some embodiments, typical bandwidths may be less than 200 MHz. In other embodiments, typical bandwidths may be less than 300 MHz. The selectivity bandwidth may be a function of the signal power level and the bandwidth may broaden as the signal power level increases.

Another characteristic of ferrite-based FSLs is that multiple notches may be generated simultaneously. That is, if multiple signals exceeding the predetermined threshold power level are injected into the FSL, notches will be generated at frequencies of each of the multiple signals simultaneously (see, e.g., FIGS. 2A, 2B).

Still another characteristic of ferrite-based FSLs is that a width of a notch (in frequency) generated in the FSL's transmission response dynamically adapts to the width (in frequency) of the above-threshold signal. That is, a notch at a frequency will be wider (i.e., will cover a wider frequency band) if a signal exceeding the predetermined threshold power level at that frequency is wider (i.e., has a wider frequency band), and a notch at a frequency will be narrower (i.e., will cover a narrower frequency band) if a signal exceeding the predetermined threshold power level at that frequency is narrower (i.e., has a narrower frequency band). A “wide” signal, as used herein, may refer to a modulated signal with some bandwidth or a spread spectrum signal, as just some examples. A person of ordinary skill in the art would recognize that there are known techniques for generating a signal with some width (i.e., frequency band), and these techniques should be considered to be within the scope of the disclosure herein.

Generally, two types of ferrite-based FSLs exist, absorptive FSLs and reflective FSLs. When an absorptive FSL receives RF signals with power levels above the predetermined threshold power level of the absorptive FSL, the absorptive FSL absorbs the above-threshold power of the RF signals. When a reflective FSL receives RF signals with power levels above the predetermined threshold power level of the reflective FSL, the reflective FSL reflects the above-threshold power of the RF signals back out of the input.

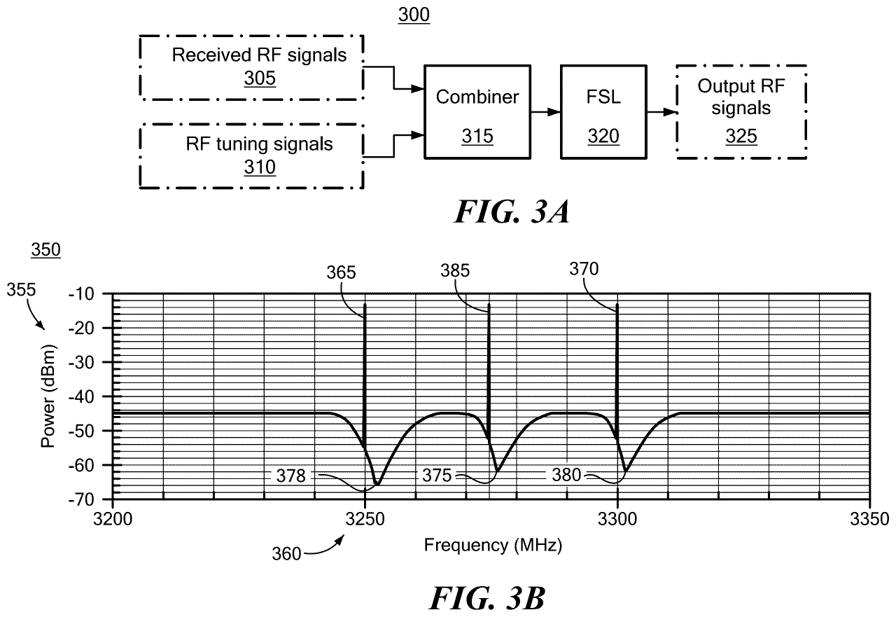

FIG. 3A shows a diagram of an example RF filter system 300, consistent with embodiments of the present disclosure. RF filter system 300 may be used, for example, to inject one or more RF tuning signals to generate filter “stop bands” or “notches” in a transmission response of an FSL. In the example of FIG. 3A, one or more RF signals 305 may be received, such as from antenna. One or more RF tuning signals 310 may be injected. The one or more RF tuning signals may have a power level that is greater than a predetermined threshold power level of the FSL. A combiner 315 may combine received RF signal(s) 305 and tuning signal(s) 310, and output the combined signals to an FSL 320. The one or more tuning signals in the combined signal may cause the transmission response of FSL 320 to have notches at frequencies corresponding to the RF tuning signal(s). FSL 320 may output RF signals 325 based on the input RF signals and the tuning signals. For example, output RF signals 325 may correspond to the RF signals input to FSL 320, but may be attenuated based on the insertion loss in the transmission response of FSL 320. That is, signals at and around the frequencies of the tuning signals may be significantly attenuated due to the notches generated in the transmission response of FSL 320. Signals that are not around the frequencies of the tuning signals may be passed linearly through FSL 320 with some low level of insertion loss common across a large frequency bandwidth, not due to the injected tuning signal(s) but rather due to an insertion loss characteristic of FSL 320 common to signals across a wide frequency band.

FIG. 3A shows received RF signal(s) 305, RF tuning signal(s) 310, and output RF signal(s) 325 in phantom, as one or more of the systems and/or components from which these signals are received and/or to which these signals are output may or may not be considered to be part of the RF filter systems discussed herein.

FIG. 3B is a graph 350 of power vs. frequency of an RF signal output resulting from example RF signals passing through an example RF filter system with example tuning signals injected. The plot shown in graph 350 may be generated by inputting RF signals into RF filter system 300, and viewing the output RF signals from FSL 320 on a spectrum analyzer. To generate the plot, a signal with a power level below a predetermined threshold power level of FSL 320 may be generated, moved across (i.e., swept across) a frequency band from 3200 MHZ to 3350 MHZ, and input to combiner 315 as received RF signal(s) 305. A signal generator may also be used to inject RF tuning signals 310 into combiner 315. The RF tuning signals may be generated with power levels above a predetermined threshold power level of FSL 320. In the example of FIG. 3B, three RF tuning signals may be generated, one a −3 dBm signal at 3.25 GHZ, one a −10 dBm signal at 3.275 GHZ, and one a −10 dBm signal at 3.3 GHZ. The combined RF signals may be output and attenuated by FSL 320. The attenuated RF signals may then be output from FSL 320 as output RF signals 325 and received by a spectrum analyzer.

Y-axis 355 of graph 350 corresponds to power in dBm, and X-axis 360 of graph 350 corresponds to frequency. The plot in graph 350 corresponds to the output RF signals that would be received by the spectrum analyzer. As shown, tuning signal 365 (−3 dBm at 3.25 GHZ) generated a notch 378 in the transmission response of FSL 320 in a frequency band around 3.25 GHz. Tuning signal 385 (−10 dBm at 3.275 GHz) generated a notch 375 in the transmission response of FSL 320 in a frequency band around 3.275 GHz. Tuning signal 370 (−10 dBm at 3.3 GHZ) generated a notch 380 in the transmission response of FSL 320 in a frequency band around 3.3 GHZ.

The number of notches, and the frequency and stop-band (i.e., how wide a frequency band the notch covers) of the notches, can be tuned by changing the tuning signals injected into the RF filter system. For example, the frequency at which a notch is generated can be tuned by changing the frequency of an injected tuning signal. The stop-band (i.e., how wide a frequency band the notch covers) at which a notch is generated can be tuned by changing the width (i.e., frequency band) and/or power of an injected signal. For example, as shown in graph 350 of FIG. 3B, tuning signal 365 (−3 dBm at 3.25 GHz) generates a wider frequency band notch 378 than tuning signal 385 (−10 dBm at 3.275 GHZ) or tuning signal 370 (−10 dBm at 3.3 GHZ), due to its higher power level. That is, notch 375 and notch 380 are narrower than notch 378, due to the higher power level of tuning signal 365.

FIG. 3B shows notches 378, 375, and 380 as being asymmetric, or slightly off center, from the frequency of the tuning signal. That is, the frequency of the center of the notch is slightly off center from the frequency of the tuning signal. This may occur due to the characteristics of the FSL used in the RF filter system (e.g., RF filter system 300). Some FSLs have characteristics that cause the center of the notch to be at a slightly higher frequency than the frequency of the tuning signal, as shown in FIG. 3B. Other FSLs have characteristics that cause the center of the notch to be at a slightly lower frequency than the frequency of the tuning signal. Some FSLs have characteristics that cause the center of the notch to be at the same frequency as the frequency of the tuning signal. Regardless, part of the notch will be at a frequency that corresponds to the frequency of the tuning signal. The disclosure herein is not limited to any particular FSL. FSLs having any of these characteristics should be considered to be within the scope of the disclosure herein.

The one or more tuning signals may be generated by a signal generator, or by components other than a signal generator, including, but not limited to, a waveform generator, an arbitrary waveform generator, an RF synthesizer, a field programmable gate array (FPGA), a software-defined radio (SDR), a voltage controlled oscillator (VCO), an antenna, or any other source, device or technique for generating RF signals now known or later discovered. A person of ordinary skill in the art would recognize that a wide variety of different types of signal generators capable of providing a variety of different types of output signals are known and available. For example, signal generators, such as arbitrary waveform generators, are known that may generate continuous wave (CW) signals, frequency modulated (FM) signals, amplitude modulated (AM) signals, pulse signals, digitally modulated signals. These signal generators may also generate signals over different frequency bandwidths. It should be appreciated that any one or more different types of signals, at any one or more different powers and/or frequency bands, may be injected into an RF filter system (e.g., filter system 300) to generate specific desired notches at specific frequencies/frequency bands. That is, a variety of different filter characteristics of an RF filter system (e.g., filter system 300) may be generated by changing the tuning signals injected into the RF filter system. The frequency and/or power of the injected tuning signals may be determined empirically based on the needs of the particular application in which the RF filter system is used.

In some embodiments, the one or more tuning signals may be injected based on one or more signals sampled from the spectrum in a received radio frequency band, such as based on one or more received RF signals 305, as will be further discussed herein.

Although resultant RF output signals based on some example injected tuning signals are shown in FIG. 3B, the disclosure is not so limited. Any number (one or more) of tuning signals can be injected, each tuning signal having a power level and width. Moreover, the power levels and widths of the tuning signals need not be the same. Any combination of signals having any number of different powers and widths may be injected to generate notches of desired frequency and width.

While tuning signals can be injected to generate notches in the FSL's transmission response, the injected tuning signals are transmitted down the receive chain, as shown in the example spectrum analyzer output shown in FIG. 3B. This may be undesirable, as the injected tuning signals can cause ill-effects on down-chain RF components, such as low noise amplifiers (LNAs), mixers, analog-to-digital converters (ADCs), and other components. Thus, it may be desirable to remove these tuning signals so that they are not transmitted down the receive chain.

Embodiments of the present disclosure provide systems and methods that may allow for generating notches in an FSL's transmission response using tuning signals, without passing the tuning signals down the receive chain. In some embodiments, an RF filter system may include tuning signal injection circuitry, such as a first ninety degree hybrid coupler, that receives one or more first RF signals and one or more second RF signals. The one or more first RF signals may include, for example, one or more signals of interest (SOI). The one or more first RF signals may also include one or more higher power signals, such as interfering signals. The one or more second RF signals may include one or more tuning signals configured to generate one or more notches in the transmission response of the RF filter system. The RF filter system may also include first and second frequency selective limiters (FSLs). The first and second FSLs may cause the RF filter system to have a transmission response with one or more notches corresponding to the one or more second RF signals, and may therefore attenuate one or more higher power signals received from the tuning signal injection circuitry. The RF filter system may also include tuning signal cancellation circuitry, such as a second ninety degree hybrid coupler, that receives RF signals from the first FSL and the second FSL and that outputs one or more RF signals. The output one or more RF signals may include the one or more signals of interest. The output one or more RF signals may not include the one or more tuning signals. Thus, the systems and methods disclosed herein may allow for injecting one or more tuning signals to generate notches in an RF filter system's transmission response, and for removal of the tuning signals from the RF filter system's output.

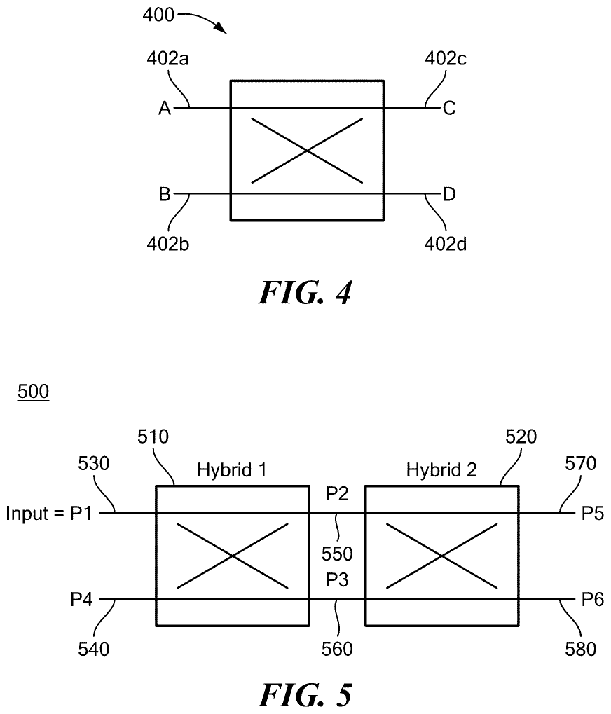

Systems described hereinbelow make use of RF devices (e.g. a single RF circuit or RF component or combinations of two or more RF circuits or RF components) which receive an input signal, split the signal with equal power, and phase shift one of the split signals by ninety degrees) (90° relative the other split signal. One example of such a device is illustrated in FIG. 4, which shows a ninety degree hybrid coupler.

Referring now to FIG. 4, shown is an example RF device 400 corresponding to a ninety degree hybrid coupler having four ports A, B, C, D labelled with respective ones of reference numerals 402a, 402b, 402c, 402d. Ninety degree hybrid coupler 400 may be implemented in any number of ways using any number of fabrication techniques and technologies and thus ports A-D may be provided as or compatible with any type of RF transmission line, such as any type of strip conductor (including but not limited to microstrip, stripline, co-planar waveguides, or a coaxial transmission line to name just a few examples). Ninety degree hybrid coupler 400 is bi-directional and thus any of ports A-D may act as an input port or an output port.

Table 1 below illustrates the properties of ninety degree hybrid coupler 400 in response to RF signals input to ports A and B. Thus, in the example of Table 1, ports A and B correspond to input ports and ports C and D correspond to outport ports.

TABLE 1

| Input | A | B | C | D |
|---|---|---|---|---|
| A | — | Isolated | −3 dB, 0° | −3 dB, 90° |
| B | Isolated | — | −3 dB, 90° | −3 dB, 0° |

As show in Table 1, an RF signal input at port A is split equally in power between ports C and D with a relative 90 degree phase shift imparted to the signals, and port B is isolated—i.e., ideally no power from the signal input at port A appears at port B (that is, one or more RF signals input to port A do not pass to port B). It is, of course, appreciated that in practical systems, the power may not be perfectly split between ports C and D and port B may not be perfectly isolated from port A (i.e., some amount of power may appear at port B as a result of an RF signal provided to port A) and that the relative phase shift imparted to the signals may not be perfectly 90 degrees. In this example, the output signal at port D is indicated as having a phase advanced by 90 degrees with respect to the output signal at port C.

Similarly, an RF signal input at port B is split equally in power between ports C and D with a relative 90 degree phase shift imparted to the signals and port A is isolated—i.e., ideally no power from the signal input at port B appears at port A (that is, one or more RF signals input port A do not pass to port B). It is, of course, appreciated that in practical systems, the power may not be perfectly split between ports C and D and port A may not be perfectly isolated from port B (i.e., some amount of power may appear at port A as a result of an RF signal provided to port B) and that the relative phase shift imparted to the signals may not be perfectly 90 degrees. In this example, the output signal at port C is indicated as having a phase advanced by 90 degrees with respect to the output signal at port D.

As can thus be seen from Table 1, one or more RF signals provided as input signals to port A may pass to both ports C and D (i.e., in this example, port A serves as an input port and ports C and D serve as output ports with the RF signals appearing at port D experiencing a phase shift of 90° relative to the RF signals appearing at port C). Since the RF signal input to port A is split equally in power between ports C and D, it may be said that the one or more RF signals at ports C and D have 3 dB less power (i.e. −3 dB) relative to the power level of the RF signal provided at port A. Such a reduction in power caused by the splitting of the input power received at one port between two output ports may be referred to as a “power split” herein.

Likewise, one or more RF signals provided as input signals to port B may pass to both output ports C and D. For example, one or more RF signals input to port B may pass to port C with 90° of phase shift relative to one or more RF signals that pass to port D, and may pass to port D with no phase shift (i.e., in this example, port B serves as an input port and ports C and D serve as output ports). The components of the outputted one or more RF signals at ports C and D resultant from one or more RF signals provided to port B may have 3 dB less power than the power level of the one or more RF signals provided to port B.

If one or more first RF signals are input to port A and one or more second RF signals are input to port B simultaneously, one or more third RF signals may be output at port C and one or more fourth RF signals may be output at port D. The one or more third RF signals may be a combination of the one or more first RF signals (with 3 dB of power split) and the one or more second RF signals (with 3 dB of power split and 90° of relative phase shift). The one or more fourth RF signals may be a combination of the one or more first RF signals (with 3 dB of power split and 90° of relative phase shift) and the one or more second RF signals (with 3 dB of power split).

As noted above, other RF devices (i.e., RF devices other than a 90° hybrid coupler) may be used to provide an equal power split and 90 degree phase shift. In embodiments, such devices may comprise one or more two-port, three-port, four-port, or N-port devices where N is any integer greater than one. For example, the same functionality as that provided by a 90 degree hybrid coupler may be provided using a combination of a variety of different RF components, including but not limited to, one or more power splitters, power combiners, power couplers, phase shifters, or the like.

As will be further discussed herein, two 90 degree hybrid couplers (or a combination of equivalent components) may be coupled together to cancel out one or more tuning signals injected into an RF filter system. For example, assuming tuning signals 365 and 370 of FIG. 3B were injected into an RF filter system, two 90 degree hybrid couplers may be used to cancel out the tuning signals after the notches have been generated in the transmission response of the FSL, such that the tuning signals do not propagate through the rest of the RF receive chain.

FIG. 5 shows an example RF system 500 where two 90 degree hybrid couplers are coupled together. A first 90 degree hybrid coupler 510 may have inputs connected to interconnects P1 (530) and P4 (540). First 90 degree hybrid coupler 510 may also have outputs connected to interconnects P2 (550) and P3 (560). A second 90 degree hybrid coupler 520 may have inputs connected to interconnects P2 (550) and P3 (560). Second 90 degree hybrid coupler 520 may also have outputs connected to interconnects P5 (570) and P6 (580).

By way of example, to illustrate how a coupling of two ninety degree hybrid couplers may operate to cancel an injected tuning signal, assume an input signal with a voltage set to 1 Volt input on interconnect P1 (530), and no input signal (0 Volts) input on interconnect P4 (540). The voltages of the signals at each interconnection of the RF system based on the input at P1 are summarized in Table 2 below, by reference to the interconnection's reference number in FIG. 5.

TABLE 2

| Reference | Signal Voltage |
|---|---|
| P1 (530) | 1 into port (full power, no phase shift), |
| | 0 out of the port (assuming no reflection) |
| P2 (550) | $\frac{- j}{\sqrt{2}} ( 1 / 2 power , - 90 degree phase shift )$ |
| P3 (560) | $\frac{- 1}{\sqrt{2}} ( 1 / 2 power , - 180 degree phase shift )$ |
| P4 (540) | 0 (isolated port) |
| P5 (570) | $\frac{- j}{\sqrt{2}} * \frac{- j}{\sqrt{2}} + \frac{- 1}{\sqrt{2}} * \frac{- 1}{\sqrt{2}} = \frac{- 1}{2} + \frac{1}{2} = 0$ |
| P6 (580) | $\frac{- j}{\sqrt{2}} * \frac{- 1}{\sqrt{2}} + \frac{- 1}{\sqrt{2}} * \frac{- j}{\sqrt{2}} = \frac{j}{2} + \frac{j}{2} = + j$ |

That is, the signal input at P1 (530) destructively interferes at P5 (570) and is cancelled, and the signal input at P1 (530) constructively interferes at P6 (580) such that a signal of 1 Volt with a phase shift of 90 degrees is output.

For a signal input at P4 (540), the opposite happens. That is, a signal input at P4 (540) will destructively interfere at P6 (580) and will constructively interfere at P5 (570). Thus, by inputting one or more received RF signals into one of ports P1 (530) and P4 (540), and one or more tuning signals into the other of ports P1 (530) and P4 (540), the one or more received RF signals may destructively interfere at one of ports P5 (570) and P6 (580) with the one or more tuning signals constructively interfering at that port, and the one or more received RF signals may constructively interfere at the other of ports P5 (570) and P6 (580), with the one or more tuning signals destructively interfering at that port.

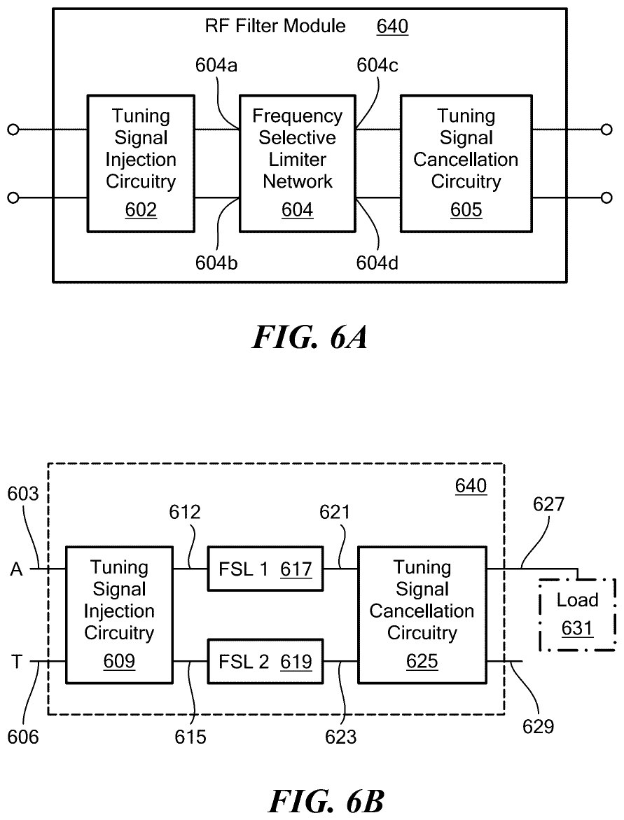

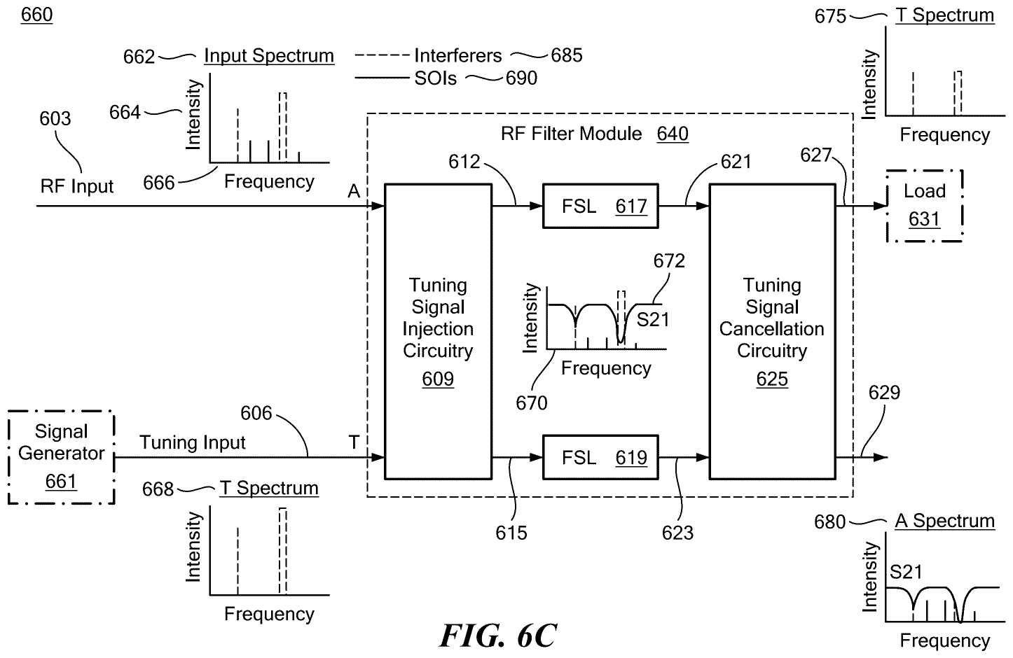

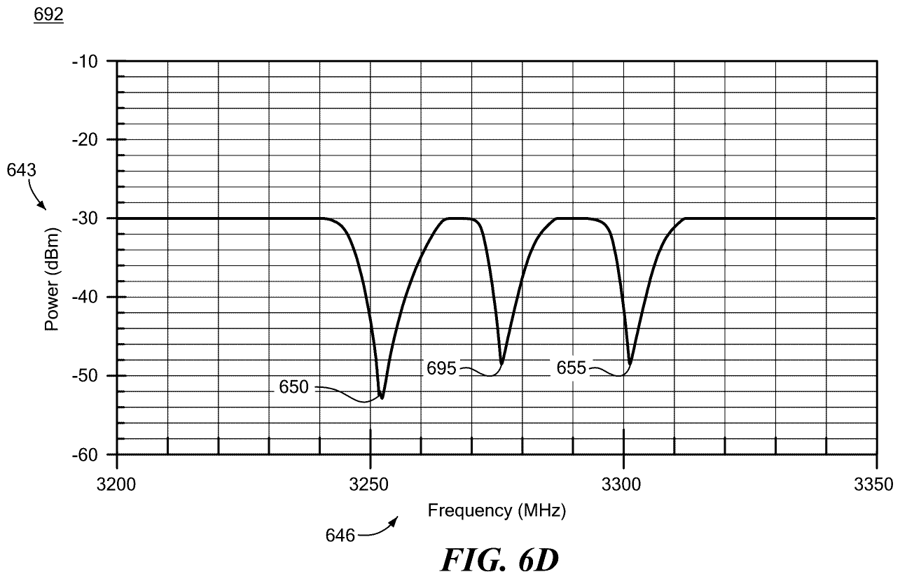

Referring now to FIG. 6A, an RF filter module 640 may include tuning signal injection circuitry 602 coupled to a first set of inputs. Tuning signal injection circuitry 602 may be coupled to inputs of an FSL network 604. A first set of outputs of FSL network 604 may be coupled to inputs of a tuning signal cancellation circuitry 605. A first set of outputs of tuning signal cancellation circuitry 605 may be coupled to a set of outputs.

Tuning signal injection circuitry 602 may comprise a 90 degree hybrid coupler. Alternatively, as discussed above, tuning signal injection circuitry 602 may comprise a combination of RF components that together provide the same functionality as a 90 degree hybrid coupler. As discussed above, the combination of RF components may include one or more power splitters, power combiners, power couplers, phase shifters, or the like.

Tuning signal cancellation circuitry 605 may comprise a 90 degree hybrid coupler. Alternatively, as discussed above, tuning signal cancellation circuitry 605 may comprise a combination of RF components that together provide the same functionality as a 90 degree hybrid coupler. As discussed above, the combination of RF components may include one or more power splitters, power combiners, power couplers, phase shifters, or the like.

In some embodiments, tuning signal injection circuitry 602 and tuning signal cancellation circuitry 605 may comprise the same types of RF components. For example, tuning signal injection circuitry 602 and tuning signal cancellation circuitry 605 may each comprise a 90 degree hybrid coupler. In some embodiments, tuning signal injection circuitry 602 and tuning signal cancellation circuitry 605 may comprise different types of components. For example, tuning signal injection circuitry 602 may comprise a 90 degree hybrid coupler and tuning signal cancellation circuitry 605 may comprise a combination of RF components that together function the same as a 90 degree hybrid coupler, or vice versa.

FSL network 604 is operably coupled to tuning signal injection circuitry 602 (e.g., via ports 604a and 604b) and is operably coupled to tuning signal cancellation circuitry 605 (e.g. via ports 604c and 604d) to provide the functionality described herein in conjunction with at least FIGS. 6B-13.

FIG. 6B shows an example RF filter system 640 with tuning signal injection circuitry 609 (e.g., a ninety degree hybrid coupler), tuning signal cancellation circuitry 625 (e.g., a ninety degree hybrid coupler) and two FSLs 617, 619, consistent with embodiments of the present disclosure. Load 631 is not properly part of the RF filter system and so is shown in FIG. 6B in phantom. RF filter system 640 may be used to inject RF tuning signals to generate notches in the transmission response of an FSL, and to remove the injected RF tuning signals such that they are not present in the RF signals output from the RF filter system.

RF filter system 640 may include tuning signal injection circuitry 609. Tuning signal injection circuitry 609 may be a ninety degree hybrid coupler, as discussed above with respect to FIG. 4. Tuning signal injection circuitry 609 may receive one or more first RF signals (represented by “A”) at an input 603. For example, the one or more RF signals may be received from an RF antenna (not shown) or any other source or receiver of RF signals. The one or more first RF signals may comprise one or more RF signals from an RF band. For example, the one or more first RF signals may be signals in an RF band from an RF antenna. Tuning signal injection circuitry 609 may also receive one or more second RF signals (represented by “T”) at an input 606. The one or more second RF signals may be one or more tuning RF signals. The one or more tuning RF signals may be generated by a signal generator, waveform generator, FPGA, SDR, VCO, or any other component or device that can generate an RF signal with a particular frequency, frequency band, and/or amplitude. Alternatively, the one or more tuning RF signals may be sampled from the input RF spectrum “A”, as further discussed herein.

One or more third RF signals may be output from a first output of tuning signal injection circuitry 609 on interconnection 612. As discussed above with respect to FIG. 4, the one or more third RF signals may include a combination of the one or more first RF signals (A minus 3 dB of power split) and the one or more second RF signals (T minus 3 dB of power split), with the output signals based on the one or more second RF signals having a 90 degree phase shift relative to the output signals based on the one or more first RF signals.

One or more fourth RF signals may be output from a second output of tuning signal injection circuitry 609 on interconnection 615. As discussed above with respect to FIG. 4, the one or more fourth RF signals may include a combination of the one or more first RF signals (A minus 3 dB of power split) and the one or more second RF signals (T minus 3 dB of power split), with the output signals based on the one or more first RF signals having a 90 degree phase shift relative to the output signals based on the one or more second RF signals.

The one or more third RF signals may be input to an input of an FSL 617 (shown as FSL 1 in FIG. 6B) from interconnection 612. FSL 617 may be, for example, an absorptive FSL or a reflective FSL. The one or more RF tuning signals from T in the one or more third RF signals may cause FSL 617 to generate notches in its transmission response.

The one or more fourth RF signals may be input to an input of an FSL 619 (shown as FSL 2 in FIG. 6B) from interconnection 615. FSL 619 may be, for example, an absorptive FSL or a reflective FSL. The one or more RF tuning signals from T in the one or more fourth RF signals may cause FSL 619 to generate notches in its transmission response.

That is, the notches in the transmission responses of the FSLs may be tuned using the one or more second RF signals (e.g., the one or more tuning RF signals). As previously discussed, the number of tuning signals, and the frequency, frequency band, and/or amplitude of each of these tuning signals, may be adjusted (i.e., tuned) to configure the frequency and/or width at which one or more notches are generated in the transmission response of an FSL (or in the case of the example in FIG. 6B, the transmission response of FSL 617 and of FSL 619). The transmission response of the FSL(s) may then be used to selectively filter interfering signals that may be received in the one or more first RF signals.

It should be appreciated that FSLs 617, 619 may or may not be the same (e.g., may or may not have the same characteristics). In some embodiments, all, some, or none of FSLs 617, 619 may be provided as polycrystalline ferrite FSLs, while in some embodiments all, some, or none of FSLs 617, 619 may be provided as single crystal ferrite FSLs. In still other embodiments, one or more FSLs may be provided as polycrystalline ferrite FSLs and one or more FSLs may be provided as single crystal ferrite FSLs. In some embodiments, FSLs 617, 619 may have the same predetermined threshold power level and/or transmission response characteristics. In some embodiments, FSLs 617, 619 may have different predetermined threshold power levels and/or different transmission responses characteristics.

One or more fifth RF signals may be output from an output of FSL 617 on interconnection 621. The one or more fifth RF signals may be the same as the one or more third RF signals but with signals at the notch frequencies having been attenuated by the notches of the FSL's transmission response, and the rest of the signals having been passed linearly through the FSL with some common, lower amount of insertion loss.

One or more sixth RF signals may be output from an output of FSL 619 on interconnection 623. The one or more sixth RF signals may be the same as the one or more fourth RF signals but with signals at the notch frequencies being significantly attenuated by the notches of the FSL's transmission response, and the rest of the signals having been passed linearly through the FSL with some common, lower amount of insertion loss.

RF filter system 640 may include tuning signal cancellation circuitry 625. The tuning signal cancellation circuitry may also be a ninety degree hybrid coupler, as discussed above with respect to FIG. 4. Tuning signal cancellation circuitry 625 may receive the one or more fifth RF signals at a first input from interconnection 621. Tuning signal cancellation circuitry 625 may also receive the one or more sixth RF signals at a second input from interconnection 623.

One or more seventh RF signals may be output from a first output of tuning signal cancellation circuitry 625 on output 627. As discussed above with respect to FIG. 5, the one or more seventh RF signals may include a combination of the one or more fifth RF signals and the one or more sixth RF signals, such that the components of the one or more fifth RF signals and the one or more sixth RF signals from the one or more first RF signals (i.e., the “A” signals) destructively interfere, and are cancelled from the one or more seventh RF signals. As also discussed above with respect to FIG. 5, the one or more seventh RF signals may include a combination of the one or more fifth RF signals and the one or more sixth RF signals, such that the components of the one or more fifth RF signals and the one or more sixth RF signals from the one or more second RF signals (i.e., the “T” signals) constructively interfere, and are present in the one or more seventh RF signals. The “T” signals present in the one or more seventh RF signals will be attenuated due to the insertion loss of the FSL. The output one or more seventh RF signals can be terminated in a load, such as load 531, shown in FIG. 6B in phantom as is it may not be properly part of the RF filter system.

One or more eighth RF signals may be output from a second output of tuning signal cancellation circuitry 625 on output 629. As discussed above with respect to FIG. 5, the one or more eighth RF signals may include a combination of the one or more fifth RF signals and the one or more sixth RF signals, such that the components of the one or more fifth RF signals and the one or more sixth signals from the one or more first RF signals (i.e., the “A” signals) constructively interfere, and are present in the one or more eighth RF signals. The “A” signals present in the one or more eighth RF signals will be attenuated due to the insertion loss of the FSL, particularly where notches were formed in the FSL's transmission response due to the injected tuning “T” signals. As also discussed above with respect to FIG. 5, the one or more eighth RF signals may include a combination of the one or more fifth RF signals and the one or more sixth RF signals, such that the components of the one or more fifth RF signals and the one or more sixth RF signals from the one or more second RF signals (i.e., the “T” signals) destructively interfere, and are cancelled from the one or more eighth RF signals.

Thus, as shown in FIG. 6B and as described above, one or more RF tuning signals may be injected into an RF filter system with tuning signal injection circuitry (e.g., a ninety degree hybrid coupler) and tuning signal cancellation circuitry (e.g., a ninety degree hybrid coupler), such as RF filter system 640, to configure the transmission response of one or more FSLs, and the one or more RF tuning signals may be removed from the signal path by the tuning signal injection circuitry and the tuning signal cancellation circuitry, such that they do not affect downstream RF components. That is, one or more tuning signals may be used to set an effective spectral filter mask of an RF filter system, and then removed from the signal path so as not to affect downstream RF components.

The discussion above assumes that the FSLs, tuning signal injection circuitry, tuning signal cancellation circuitry, and interconnections of the RF filter system of FIG. 6B are matched. If components in the RF filter system are not matched, additional components may be required to adjust the phase shift and/or gain of the signals in the RF filter system. Such additional components may not be required if the tuning signal injection circuitry, tuning signal cancellation circuitry, FSLs, and interconnect paths are matched.

Although ninety degree hybrid couplers have been provided above as examples of tuning signal injection circuitry 609 and tuning signal cancellation circuitry 625, the disclosure is not so limited. A person of ordinary skill in the art would recognize that a ninety degree hybrid coupler may be replaced by one or more components that function to provide similar output signals. For example, as previously discussed, the same function as that provided by a ninety degree hybrid coupler may be provided with a combination of other RF components, such as one or more power splitters, power combiners, power couplers, phase shifters, or the like. Any known technique, using one or more components, to phase shift one of the input signals and then combine the phase-shifted input signal with another input signal that was not phase shifted may be used in place of a ninety degree hybrid coupler in tuning signal injection circuitry 609 and/or tuning signal cancellation circuitry 625, and should be considered to be within the scope of the disclosure herein.

FIG. 6C shows a diagram 660 of an example RF filter system 640 consistent with embodiments of the present disclosure, and of graphs of spectra for example signals at different stages in the example RF filter system. RF filter system 640 may be the same as RF filter system 640 discussed above with respect to FIG. 6B, and may operate in the same fashion.

Graph 662 shows a plot of a spectrum of example RF signals from a frequency band received into input 603 as the “A” signals. Graph 662 includes a Y-axis 664 that corresponds to intensity (i.e., power) and an X-axis 666 that corresponds to frequency. Graph 662 includes a plot that shows interfering signals 685 at two frequencies/frequency bands and signals of interest (SOIs) 690 at three frequencies/frequency bands. As shown, the interfering signals may have a higher power level than the SOIs.

Graph 668 shows a plot of a spectrum of example RF signals from a frequency band provided into input 606 as the tuning “T” signals. The tuning signals may be generated, for example, by a signal generator 661, which may be a signal generator, waveform generator, arbitrary waveform generator, RF synthesizer, FPGA, SDR, VCO, antenna, or any other component or device that can generate one or more RF signals, each of the one or more RF signals having a particular frequency, frequency band, and/or amplitude. Signal generator 661 is shown in FIG. 6C in phantom, as it may not be properly part of the RF filter system. Alternatively, as discussed further herein, the tuning “T” signals may be sampled from the input “A” spectrum. Graph 668 includes a Y-axis corresponding to intensity and an X-axis corresponding to frequency, as discussed above with respect to graph 662. Graph 668 includes a plot that shows tuning signals generated at two frequencies/frequency bands, corresponding to the frequencies of the interfering signals. The tuning signals may also have intensities that correspond to the intensities of the interfering signals, and/or widths (in frequency band) that correspond to the widths (in frequency band) of the interfering signals. That is, the tuning signals may be configured to generate notches in the RF filter system's FSL transmission response so as to cause the interfering signals to be attenuated. For example, a user could configure signal generator 661 to generate the desired tuning signals, or feedback may be incorporated such that the interfering signals are identified and feedback provided to set signal generator 661 to generate the desired tuning signals. Alternatively, the desired tuning signals may be generated automatically by sampling them from the input “A” spectrum, as further discussed herein.

Graph 672 shows a plot of a spectrum of example RF signals received at the FSLs 617, 619, and of the transmission response generated in the FSLs in response to the tuning signals (i.e., “T” signals). Graph 672 includes a Y-axis corresponding to intensity and an X-axis corresponding to frequency, as discussed above with respect to graph 662. The S21 curve in graph 672 represents the transmission response that the “T” signals may generate in the FSLs. That is, the S21 curve represents the insertion loss that occurs as the one or more third RF signals pass from an input port (e.g., S1) to an output port (e.g., S2) of FSL 617, or as the one or more fourth RF signals pass from an input port (e.g., S1) to an output port (e.g., S2) of FSL 619. This transmission response of the FSL may be used to selectively filter the interfering signals. As can be seen from graph 672, the tuning signal that is greater in intensity and wider in width (i.e., frequency band) generates a deeper and wider notch in the transmission response of the FSL than the tuning signal that is smaller in intensity and narrower in width (i.e., frequency band).

Graph 675 shows a plot of a spectrum of example RF signals output out of a first output of tuning signal cancellation circuitry 625. Graph 675 includes a Y-axis corresponding to intensity and an X-axis corresponding to frequency, as discussed above with respect to graph 662. As can be seen from graph 675, the RF signals output from the first output of tuning signal cancellation circuitry 625 are the tuning “T” signals minus the insertion loss of an FSL.

Graph 680 shows a plot of a spectrum of example RF signals output from a second output of tuning signal cancellation circuitry 625. Graph 680 includes a Y-axis corresponding to intensity and an X-axis corresponding to frequency, as discussed above with respect to graph 662. Graph 680 includes curve S21 to show the effect the FSL's transmission response had on the signals. As can be seen from graph 680, the RF signals output from the second output of tuning signal cancellation circuitry 625 are the “A” signals, but with the interfering signals having been attenuated. More specifically, the “RF signals output from the second output of tuning signal cancellation circuitry 625 are the “A” signals minus the insertion loss of an FSL, which particularly attenuates the interfering signals in the “A” signals due to the notches in the FSL's transmission response.

FIG. 6D shows a graph 692 of example measured output RF signals from example RF filter system 640 after example tuning signals were injected into RF filter system 640. Graph 692 includes a Y-axis 643 corresponding to intensity in dBm, and an X-axis 646 corresponding to frequency. The example tuning signals injected into the RF filter system here were a a −3 dBm tuning signal at 3.25 GHZ, a −10 dBm tuning signal at 3.275 GHz, and a −10 dBm tuning signal at 3.3 GHZ. As shown in FIG. 6D, a resulting notch 650 appears at or around 3.25 GHZ (corresponding to the −3 dBm tuning signal at 3.25 GHZ), another resulting notch 695 appears at or around 3.275 GHz (corresponding to the −10 dBm tuning signal at 3.275 GHZ), and still another resulting notch 655 appears at or around 3.3 GHZ (corresponding to the −10 dBm tuning signal at 3.3 GHZ). As shown in FIG. 6D, using the RF filter system of FIGS. 6B and 6C, notches were generated in the transmission response of the FSL, but in contrast to graph 350 in FIG. 3B, the tuning signals were cancelled from the output RF signals due to the tuning signal injection circuitry and tuning signal cancellation circuitry in the RF filter systems of FIGS. 6B and 6C.

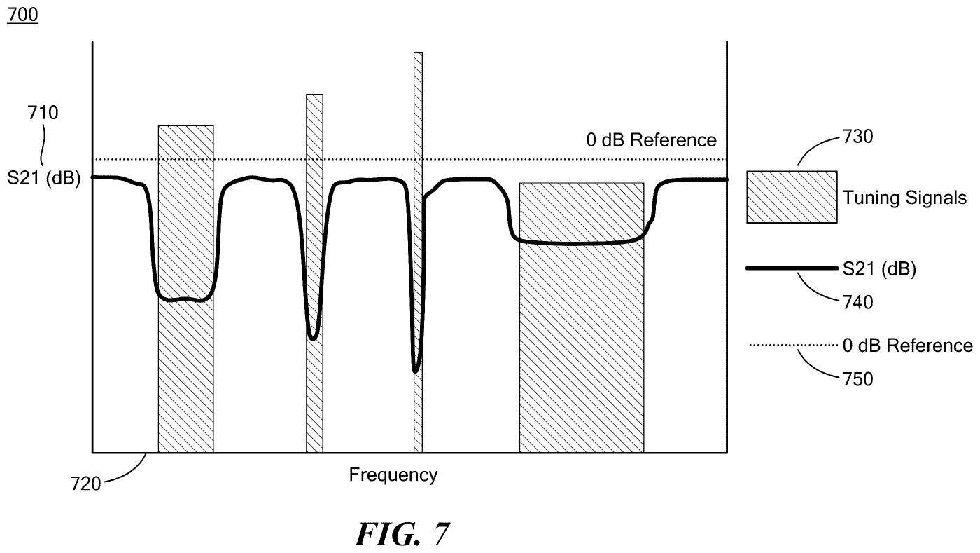

FIG. 7 shows a graph 700 of example tuning signals and an example transmission response of an example RF filter system consistent with embodiments of the present disclosure. Graph 700 includes a Y-axis 710 corresponding to intensity in dB, and an X-axis 720 corresponding to frequency. Signals 730 represent example tuning signals injected into an RF filter system, such as RF filter system 640 of FIGS. 6B and 6C, and curve S21 740 represents the transmission response of the FSL(s) generated by the tuning signals. Line 750 represents 0 dB as a reference.

Using an RF filter system with FSLs, tuning signal injection circuitry, and tuning signal cancellation circuitry, as shown in FIGS. 6B and 6C and discussed above, the RF filter system may be customized and/or reconfigured to provide a transmission response with any number of notches of different depths and/or widths, allowing for creation of a vast number of different filter patterns. Moreover, these filter patterns may be rapidly reconfigured by changing the tuning signal input into the RF filter system. Thus, such an approach may offer significant improvements over other approaches to RF signal filtering.

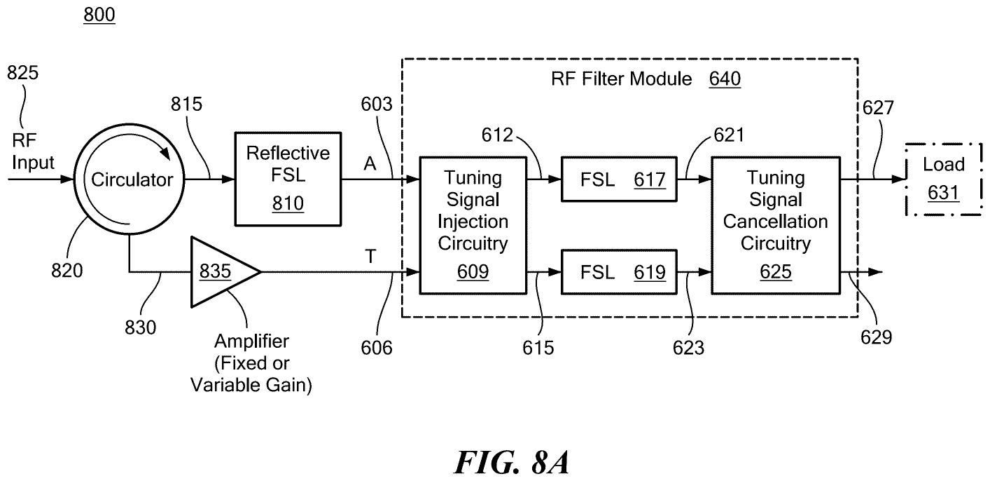

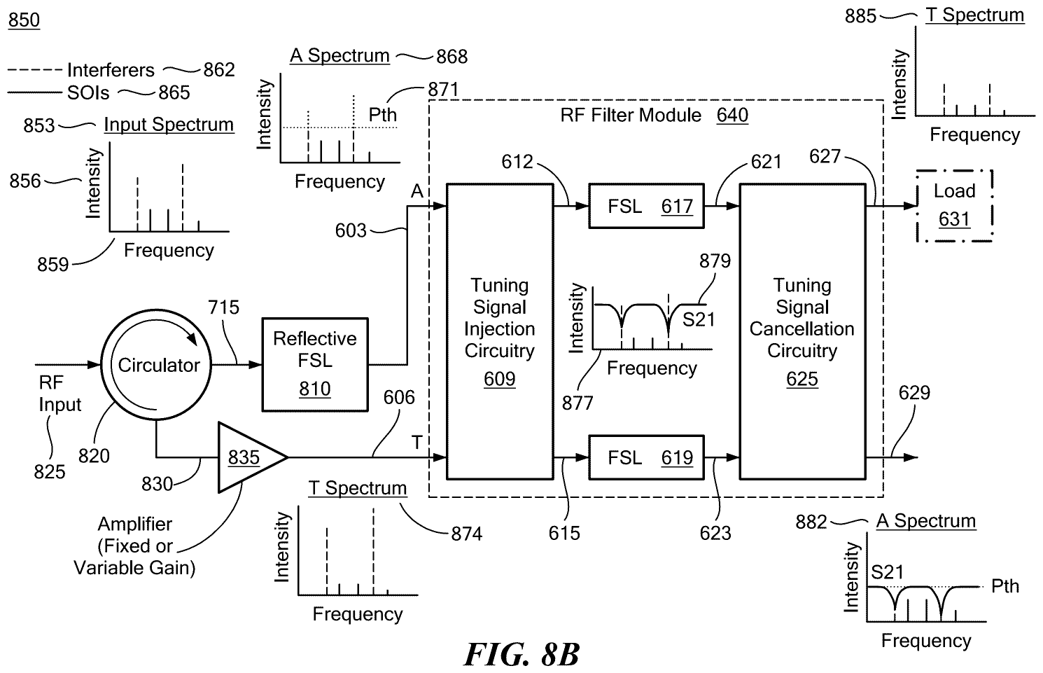

FIG. 8A shows a diagram of another example RF filter system 800 that may include a reflective FSL 810, a circulator 820, and an amplifier 835 in addition to the components of RF filter system 640 previously discussed. The addition of reflective FSL 810, circulator 820, and amplifier 835 may allow RF filter system 800 to self-tune, rather than requiring one or more tuning signals to be generated by a signal generator.

RF filter system 800 may receive one or more RF input signals at an input 825 to a circulator 820. The one or more RF input signals may include one or more signals of interest (SOI). The one or more RF input signals may also include one or more interfering signals. As one example, the one or more RF input signals may be signals such as the example signals shown in graph 662 of FIG. 6C.

Circulator 820 may receive the one or more RF input signals and pass them over interconnection 815 to reflective FSL 810. If a power level of one or more of the one or more RF input signals is greater than or equal to a predetermined power level threshold of reflective FSL 810, the portion of the energy of the one or more RF signals that is equal to or above the predetermined power level threshold may be reflected by reflective FSL 810 back to circulator 820, while the portion of the energy of the one or more RF signals that is below the predetermined power level threshold may be passed through reflective FSL 810 and may enter RF filter module 640 as the one or more first RF signals (i.e., the one or more “A” RF signals). Circulator 820 may pass the reflected one or more RF signals to amplifier 835 over interconnection 830. Amplifier 835 may be, for example, a fixed or variable gain amplifier. At amplifier 835, the one or more reflected RF signals may receive gain, and may then enter RF filter module 640 as the one or more second RF signals (i.e., the one or more “T” signals).

In some embodiments, the predetermined power level threshold of reflective FSL 810 may be the same or substantially the same as the predetermined power level threshold of FSL 617 and FSL 619, though the disclosure is not so limited. The one or more “A” RF signals, having passed through reflective FSL 810, may therefore all have power levels that are below the predetermined power level thresholds of FSLs 617 and 619. The one or more “T” RF signals, having been reflected by reflective FSL 810 and amplified by amplifier 835, may all have power levels above the predetermined power level thresholds of FSLs 617 and 619 and may therefore be used as the tuning signals, as previously discussed with respect to FIGS. 6A-6D and 7. RF filter module 640 may operate on these “A” and “T” signals in the same manner as previously discussed, whereby the “T” signals constructively arrive at the first output of tuning signal cancellation circuitry 625 and the “A” signals constructively arrive at the second output of tuning signal cancellation circuitry 625.

FSL 810 may be provided as a polycrystalline ferrite FSL or as a single crystal ferrite FSL. As discussed above, FSL 810 may have the same predetermined threshold power level as FSL 617 and/or FSL 619. However, the disclosure is not so limited. In some embodiments, FSL 810 may have a different predetermined threshold power level than FSL 617 and/or FSL 619.

FIG. 8B shows a diagram 850 of an example RF filter system that includes a reflective FSL 810, a circulator 820, and an amplifier 835, consistent with embodiments of the present disclosure, and graphs of example spectra for different signals in the example RF filter system. The RF filter system of FIG. 8B may be the same as RF filter system 800.

Graph 853 shows a plot of a spectrum of example RF signals from a frequency band provided into the input of circulator 820. Graph 853 includes a Y-axis 856 that corresponds to intensity (i.e., power) and an X-axis 859 that corresponds to frequency. Graph 853 includes a plot that shows interfering signals 862 at two frequencies and signals of interest (SOIs) 865 at three frequencies. As shown, the interfering signals may have a higher power level than the SOIs.

Graph 868 shows a plot of a spectrum of example RF signals received by reflective FSL 810 over interconnect 815 from circulator 820. Graph 868 includes a Y-axis that corresponds to intensity and an X-axis that corresponds to frequency, as discussed above with respect to graph 853. Line 871 (“Pth”) corresponds to the predetermined power level threshold of reflective FSL. The solid lines in graph 868 represent signal intensity of SOIs that passes through reflective FSL 810, the dashed lines in graph 868 represent signal intensity of interfering signals that pass through FSL 810, and the dotted lines in graph 868 represent signal intensity of the interfering signals that is reflected by reflective FSL 810 back to circulator 820 over interconnect 815. The signal intensity corresponding to the solid lines and dashed lines may be passed through reflective FSL 810 into input 603 of the RF filter module 640 as the one or more first RF signals (i.e., the one or more “A” signals).

Graph 874 shows a plot of a spectrum of example reflected RF signals received from circulator 820 over interconnect 830 after gain has been applied at amplifier 835. Graph 874 includes a Y-axis that corresponds to intensity and an X-axis that corresponds to frequency, as discussed above with respect to graph 853. The signals shown in graph 874 may be passed into input 606 of the RF filter module 640 as the one or more second RF signals (i.e., the one or more “T” signals). As shown in graph 874, the signals received from circulator 820 may also include attenuated SOI signals, as circulator 820 may only provide a certain degree of isolation and as a result some power of the SOI signals may leak through circulator 820.

Graph 879 shows a plot of a spectrum of example RF signals received at FSLs 617, 619, and the transmission response of the FSLs in response to the tuning signals (i.e., the “T” signals). Graph 879 includes a Y-axis corresponding to intensity and an X-axis corresponding to frequency, as discussed above with respect to graph 853. The S21 curve in graph 879 represents the transmission response that the “T” signals may generate at the FSLs. That is, the S21 curve represents the insertion loss that occurs as the one or more third RF signals pass from an input port (e.g., S1) to an output port (e.g., S2) of FSL 617, or as the one or more fourth RF signals pass from an input port (e.g., S1) to an output port (e.g., S2) of FSL 619. This transmission response may be used to selectively filter the interfering signals. As can be seen from graph 879, the tuning signal that is greater in intensity generates a deeper notch in the transmission response than the tuning signal that is smaller in intensity.

Graph 885 shows a plot of a spectrum of example RF signals output out of a first output (e.g., output 627) of tuning signal cancellation circuitry 625. Graph 885 includes a Y-axis corresponding to intensity and an X-axis corresponding to frequency, as discussed above with respect to graph 853. As can be seen from graph 885, the RF signals output from the first output of tuning signal cancellation circuitry 625 are the tuning “T” signals, or more specifically, the “T” signals minus the insertion loss of an FSL.

Graph 882 shows a plot of a spectrum of example RF signals output out of a second output (e.g., output 629) of tuning signal cancellation circuitry 625. Graph 882 includes a Y-axis corresponding to intensity and an X-axis corresponding to frequency, as discussed above with respect to graph 853. Graph 882 includes curve S21 to show the effect the FSL transmission response had on the signals. “Pth” corresponds to the power level threshold of the FSLs. As can be seen from graph 882, the RF signals output from the second output of tuning signal cancellation circuitry 625 are the “A” signals, but with the interfering signals having been attenuated. More specifically, the RF signals output from the second output of tuning signal cancellation circuitry 625 are the “A” signals minus the insertion loss of the FSL, which particularly attenuates the signals (e.g., interfering signals) at frequencies corresponding to the notches generated in the FSL's transmission response.

Thus, as described above with respect to FIGS. 8A and 8B, one or more RF signals (e.g., high power interfering signals) may be sampled from an input RF spectrum by a reflective FSL, and used as the tuning signals to generate notches that attenuate the interfering signals. As a result, RF filter system 800 may be used as a reference-less self-tuning RF filter that can create any number of different notches at different frequencies, depths, and/or widths, and that may automatically reconfigure itself based on changes in incoming interfering signals. Moreover, RF filter system 800 may passively reconfigure itself based on changes in incoming interfering signals, without needing any sort of computing or sense-and-control feedback loops.

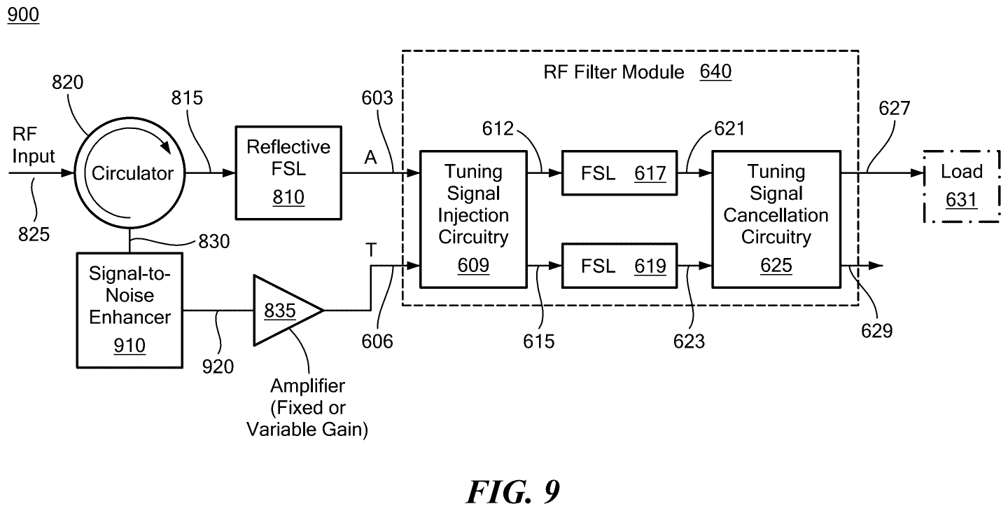

FIG. 9 shows a diagram of an example RF filter system 900 that includes a reflective FSL 810, a circulator 820, a signal-to-noise enhancer 910, and an amplifier 835, consistent with embodiments of the present disclosure. The addition of signal-to-noise enhancer 910 may further help to increase the dynamic range between RF signals that are above a predetermined power level threshold and RF signals that are below a predetermined power level threshold (e.g., increase the dynamic range between the interfering signals and SOI signals to be input as “T” signals shown in graph 874 of FIG. 8B). Such an increase in dynamic range may result in improved rejection of interfering signals that are above the predetermined power level threshold.

Signal-to-noise enhancer 910 may receive one or more reflected RF signals from reflective FSL 810 via circulator 820 over interconnect 830. Signal-to-noise enhancer 910 may be a ferrite-based component that has an opposite effect on RF signals than the FSL components. That is, rather than attenuate RF signals above a predetermined power level threshold and allow below-threshold signals to pass with low loss, signal-to-noise enhancer 910 may attenuate RF signals that are below a predetermined power level threshold and may allow RF signals with power levels above the predetermined power level threshold to pass with low loss. The one or more RF signals output from signal-to-noise enhancer 910 may then be passed to amplifier 835 over interconnect 835, and amplifier 835 may pass an amplified version of these signals on as the tuning “T” signals, as discussed above with respect to FIGS. 8A and 8B. Thus, by positioning signal-to-noise enhancer 910 in RF filter system 900 at the position shown in FIG. 9, signal-to-noise enhancer 910 may increase the dynamic range between above-threshold and below-threshold signals, ultimately resulting in improved rejection of the above-threshold interfering signals.

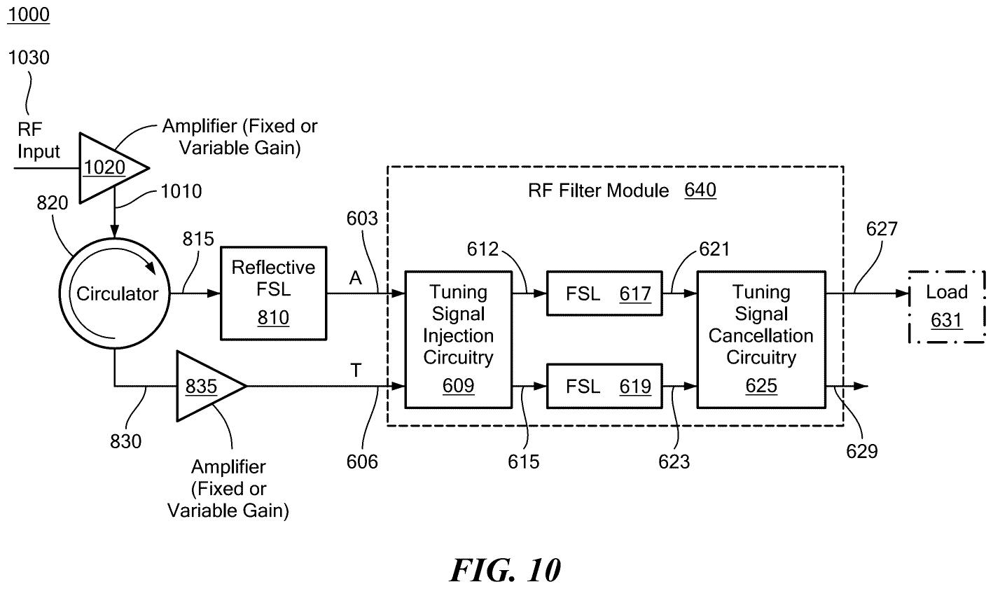

FIG. 10 shows a diagram of an example RF filter system 1000 that includes a reflective FSL 810, a circulator 820, a first amplifier 835, and a second amplifier 1020. RF filter system 1000 may be the same as RF filter system 800, where first amplifier 835 of RF filter system 1000 corresponds to amplifier 835 of RF filter system 800 and second amplifier 1020 has been added in RF filter system 1000. Second amplifier 1020 may be a fixed or variable gain amplifier. Inserting second amplifier 1020 before circulator 820 and reflective FSL 810, as shown in FIG. 10, may help to preserve an overall noise figure of the RF filter system, help enable control over an effective power threshold of reflective FSL 810, and/or help enable potential active tuning of an effective power threshold of reflective FSL 810. For example, in some environments where the received RF input signals are not high power, the RF input signals may need to be amplified by an amplifier 1020 to be used by the rest of system 1000. In some embodiments, amplifier 1020 is a variable gain amplifier, which allows dynamic adjustment of the power level of the RF input signals input to RF filter system 1000, thereby providing active tuning of an effective power threshold of reflective FSL 810.

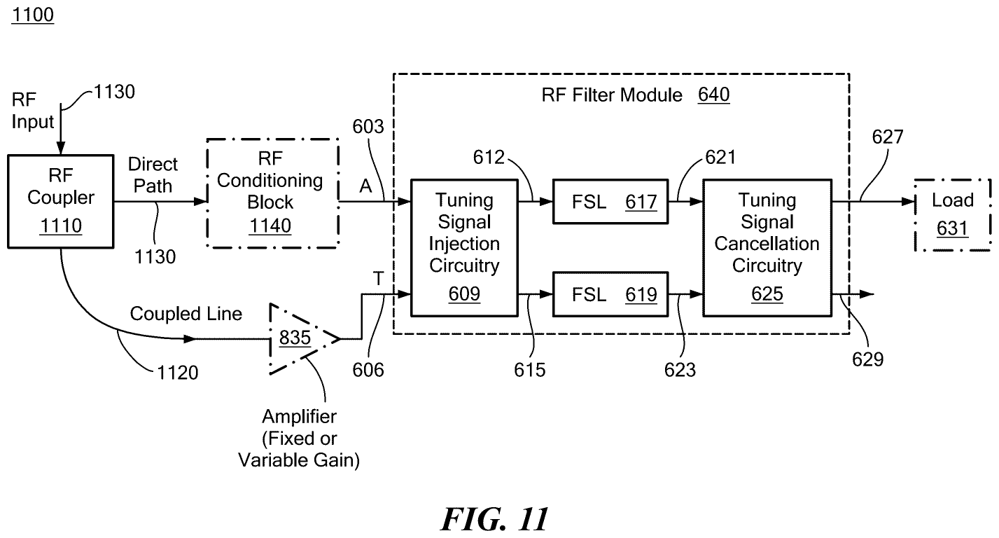

FIG. 11 shows a diagram of an example RF filter system 1100 that includes an RF coupler 1110, an optional RF conditioning block 1140, and an optional amplifier 835, consistent with embodiments of the present disclosure. RF filter system 1100 may be used as a reference-less, self-tuning RF filter system when a ratio of a power level of an interferer signal to a power level of an SOI is expected to be high. When the ratio of the interferer signal power level to the SOI power level is high (e.g., interferer signal power level is 70 dB higher), an RF coupler 1110 may direct a feed from RF input 1130 over a coupled line 1120 as the one or more signals to inject as the “T” tuning signals. For example, when the interferer signals of an RF input are at a much higher power level than the SOI signals of the RF input, the signals of the RF input may be coupled directly for use as the tuning “T” signals to generate the desired notches in the transmission response of the FSLs in the RF filter system. In some embodiments, an amplifier (e.g., fixed or variable gain amplifier) may be coupled between RF coupler 1110 and the tuning signal “T” input to RF filter module 640, so as to amplify the signals to compensate for loss from RF coupler 1110 or to otherwise boost the signals to an even higher power level before injecting them as tuning “T” signals into RF filter module 640.

The RF input signals may also be coupled through RF coupler 1110 over a direct path 1130 for use as “A” signals. For example, the high power interferer signals in the tuning “T” signals may generate sufficient notches such that the interferer signals in the “A” signals are significantly attenuated, leaving substantially only the SOI signals in the “A” signals to pass out of RF filter module as signals 629. In some embodiments, an RF conditioning block 1140 may be coupled between RF coupler 1130 and the “A” signal input to RF filter module 640. RF conditioning block 1140 may include signal conditioning circuitry or components, such as an FSL or an auto-tune filter (ATF), to reduce the amplitude of the interferer signals. For example, when the RF input signals 1130 include interferer signals of very high power, the very high power signals could cause damage to the RF filter module circuitry and/or components if the power level is not attenuated before being introduced into RF filter module 640. Thus, one or more components in RF conditioning block 1140 may act to attenuate those signals, so as not to damage the components of RF filter module 640 or any other downstream components.

In some embodiments, another amplifier may be coupled between the RF input signals and RF coupler 1110. For example, as discussed with respect to FIG. 10, adding such an additional amplifier may help to preserve an overall noise figure of the RF filter system.

Use of RF filter system 1100 may accomplish objectives of a particular application, such as preserving overall noise figure, isolating interferer signals from SOI signals when there is a considerable power level difference between the interferer signals and the SOI signals, and conditioning the direct path (when an RF conditioning block 1140 is included), so as to reduce the interferer to SOI signal power level ratio and prevent damage to components of RF filter module 640 or other downstream components.

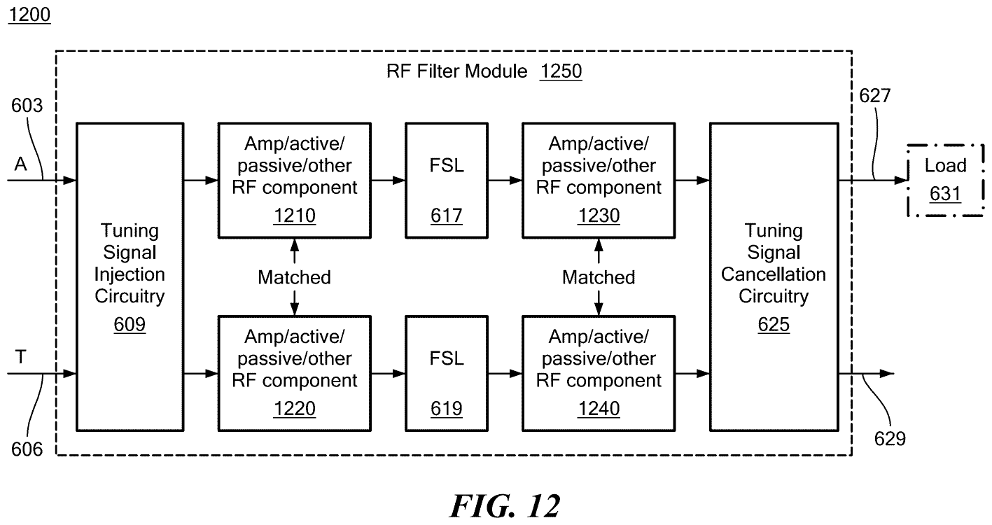

FIG. 12 shows a diagram of an RF filter module 1250. Like RF filter module 640, RF filter module 1250 may be configured to receive one or more first RF signals (“A” signals) at a first input and one or more second RF signals (“T” signals) at a second input. Like RF filter module 640, RF filter module 1250 may include tuning signal injection circuitry 609, FSLs 617, 619, and tuning signal cancellation circuitry 625. Like RF filter module 640, RF filter module 1250 may output from one port RF signals comprising tuning “T” signals to a load 631, and may output from another port RF signals comprising “A” signals (SOIs). RF filter module 1250 may also include one or more additional matched components, such as additional matched components 1210, 1220, and additional matched components 1230, 1240. The additional matched components may include components such as amplifiers, phase shifters, filters, active components, passive components, or other RF components. In some embodiments, matched components may be coupled before FSLs 617, 619, such as matched components 1210, 1220. In some embodiments, matched components may be coupled after FSLs 617, 619, such as matched components 1230, 1240. In some embodiments, matched components may be added both before and after FSLs 617, 619, as shown in FIG. 12. Any number of matched components may be added before and/or after FSLs 617, 619. The matched components may, for example, be included to provide favorable analog signal processing for RF filter module 1250. As just one example, matched amplifiers may be added to help improve an interferer signal to SOI signal power level ratio.

Although different systems (e.g., RF filter system 660, RF filter system 800, RF filter system 850, RF filter system 900, RF filter system 1000, RF filter system 1100, RF filter system 1200) have been separately described above, one or more components of any one system may be used in combination with components of another system to achieve a desired result. For example, the RF coupler, RF conditioning block, and/or amplifier of system 1100 may be used with another system such that, when high power interferer signals are expected, the RF coupler, RF conditioning block, and/or amplifier are used, and when high power interferer signals are not expected, they are not used. As another example, a reflective FSL and circulator may be provided along with a signal generator such that, when interferer signals are expected to be received, the reflective FSL and circulator may be used to automatically inject the interferer signals as tuning “T” signals, and when interferer signals are not expected to be received, tuning “T” signals could be generated by signal generator. Any number of different combinations of components may be utilized together to provide a desired result depending on application.

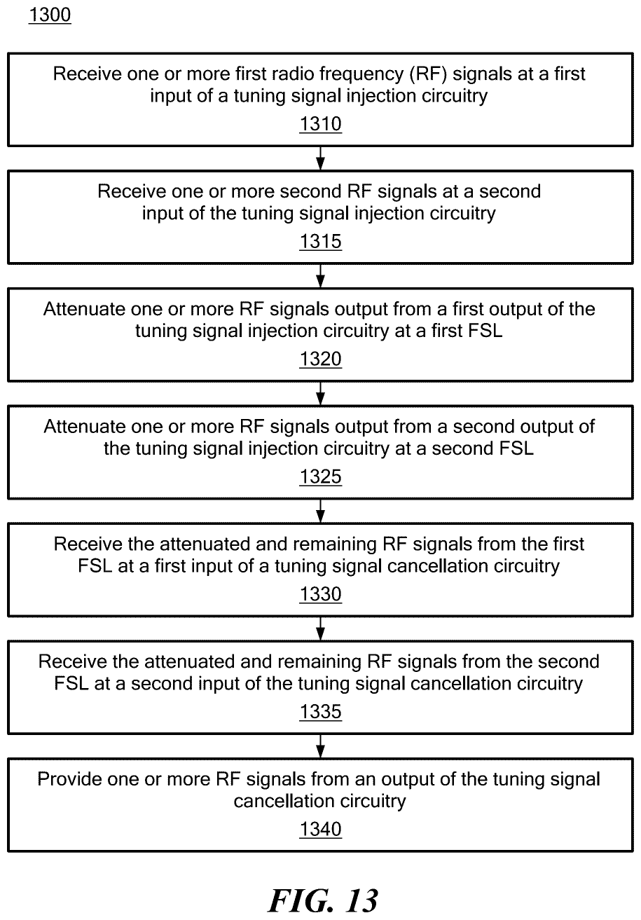

FIG. 13 shows an example process 1300 for filtering RF signals, consistent with embodiments of the present disclosure. Process 1300 may be carried out by an RF filter system, such as RF filter system 640, RF filter system 660, RF filter system 800, RF filter system 900, RF filter system 1000, RF filter system 1100, or RF filter system 1200.

In 1310, one or more first RF signals may be received at a first input (e.g., input 603) of tuning signal injection circuitry (e.g., tuning signal injection circuitry 609). For example, as previously discussed, the one or more first RF signals may correspond to the “A” signals, which may include one or more signals of interest (SOI) and/or one or more interfering signals.

In 1315, one or more second RF signals may be received at a second input (e.g., input 606) of the tuning signal injection circuitry (e.g., tuning signal injection circuitry 609). For example, as previously discussed, the one or more second RF signals may correspond to the “T” signals, which may include one or more tuning signals.

One or more third RF signals may be output from a first output of the tuning signal injection circuitry (e.g., tuning signal injection circuitry 609) on an interconnect (e.g., interconnect 612) and received by a first FSL (e.g., FSL 617). In 1320, the first FSL (e.g., FSL 617) may attenuate one or more of the one or more third RF signals based on a frequency of the one or more of the third RF signals, and may pass the attenuated one or more RF signals and the remaining RF signals as one or more fifth RF signals on an interconnect (e.g., interconnect 621). For example, the first FSL may attenuate one or more of the one or more third RF signals based on a frequency of the one or more signals and based on a frequency of one or more notches in the transmission response of the first FSL.

One or more fourth RF signals may be output from a second output of the tuning signal injection circuitry (e.g., tuning signal injection circuitry 609) on an interconnect (e.g., interconnect 615) and received by a second FSL (e.g., FSL 619). In 1325, the second FSL (e.g., FSL 619) may attenuate one or more of the one or more fourth RF signals based on a frequency of the one or more of the fourth RF signals, and may pass the attenuated one or more RF signals and the remaining RF signals as one or more sixth RF signals on an interconnect (e.g., interconnect 623). For example, the second FSL may attenuate one or more of the one or more fourth RF signals based on a frequency of the one or more signals and based on a frequency of one or more notches in the transmission response of the second FSL.

In 1330, the one or more fifth RF signals may be received at a first input of a tuning signal cancellation circuitry (e.g., tuning signal cancellation circuitry 625).

In 1335, the one or more sixth RF signals may be received at a second input of the tuning signal cancellation circuitry (e.g., tuning signal cancellation circuitry 625).

One or more seventh RF signals may then be provided from a first output (e.g., first output 627) of the tuning signal cancellation circuitry (e.g., tuning signal cancellation circuitry 625). The one or more seventh RF signals may be the tuning “T” signals, or more specifically, the “T” signals minus the insertion loss of an FSL, as discussed above with respect to FIGS. 6A and 6B.

In 1340, one or more eighth RF signals may be provided from a second output (e.g., second output 629) of the tuning signal cancellation circuitry (e.g., tuning signal cancellation circuitry 625). The one or more eighth RF signals may be the “A” signals, or more specifically, the “A” signals minus the insertion loss of an FSL, which particularly attenuates signals (e.g., interfering signals) at frequencies corresponding to the notches generated in the FSL's transmission response, as discussed above with respect to FIGS. 6A and 6B.

Thus, as previously discussed, the output (e.g., second output 629) of the RF filter system may include an RF spectrum that includes one or more signals of interest, with one or more interfering signals having been significantly attenuated by notches in the transmission responses of FSL(s), and with tuning signals used to generate the notches having been removed.

A person of ordinary skill in the art would recognize that the interconnects described herein may be any type of transmission line capable of transmitting RF signals. For example, the interconnects may be any combination of one or more of co-planar waveguide, microstrip, stripline, coaxial, or any other type RF transmission line.

A person of ordinary skill in the art would recognize that the components discussed herein (e.g., couplers, FSLs, circulators, amplifiers, signal-to-noise enhancers) may have ports allowing RF signals to pass into and out of the components, and allowing the components to connect to interconnects. Any type of port that may be used to connect to any of the aforementioned types of transmission lines may be used, and should be considered to be within the scope of the disclosure herein.

Further, it is noted that various connections and positional relationships (e.g., over, below, adjacent, etc.) may be set forth between elements in the foregoing description and in the drawings. These connections and/or positional relationships, unless specified otherwise, can be direct or indirect, and the described systems and methods are not intended to be limiting in this respect. Accordingly, a coupling of entities can refer to either a direct or an indirect coupling, and a positional relationship between entities can be a direct or indirect positional relationship.

As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, system, or apparatus that comprises a list of elements is not necessarily limited to only those elements but can include other elements not expressly listed or inherent to such composition, mixture, process, method, article, system, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The phrase “one or more” is to be understood to include any integer number greater than or equal to one, i.e., one, two, three, four, etc. The phrase “a plurality” is to be understood to include any integer number greater than or equal to two, i.e., two, three, four, five, etc. The term “connection” should be considered as including an indirect “connection” and/or a direct “connection.”

References in the specification to “one embodiment, “an embodiment,” “an example embodiment,” “some embodiments,” etc., indicate that the embodiment(s) described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

It should be understood that characteristics of electrical components may vary slightly depending on, for example, manufacturing tolerances. It should therefore be understood that when specific values or relative values (e.g., referring to some value as the “same” as another value) are discussed herein, that those values may vary from what is discussed by anywhere from within ±2% of each other to within ±30% of each other. That is, values that vary within a degree from the values discussed should be considered to be within the scope of the values discussed herein.

The terms “approximately” and “about” may be used to mean within ±20% of a target value in some embodiments, within ±10% of a target value in some embodiments, within ±5% of a target value in some embodiments, and within ±2% of a target value in some embodiments. The terms “approximately” and “about” may include the target value. The term “substantially equal” may be used to refer to values that are within ±20% of one another in some embodiments, within ±10% of one another in some embodiments, within±5% of one another in some embodiments, and within ±2% of one another in some embodiments.

The term “substantially” may be used to refer to values that are within ±20% of a comparative measure in some embodiments, within ±10% in some embodiments, within ±5% in some embodiments, and within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other systems and methods for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

1. A radio frequency (RF) filter system, comprising:
tuning signal injection circuitry with a first input configured to receive one or more first RF signals and a second input configured to receive one or more second RF signals; and
a first frequency selective limiter (FSL) coupled to a first output of the tuning signal injection circuitry.

2. The RF filter system of claim 1, further comprising:
a second FSL coupled to a second output of the tuning signal injection circuitry; and
tuning signal cancellation circuitry coupled to an output of the first FSL and to an output of the second FSL.

3. The RF filter system of claim 2, wherein the first FSL is configured to attenuate one or more RF signals received from the first output of the tuning signal injection circuitry and having one or more frequencies corresponding to one or more notches in a transmission response of the first FSL.

4. The RF filter system of claim 2, wherein the second FSL is configured to attenuate one or more RF signals received from the second output of the tuning signal injection circuitry and having one or more frequencies corresponding to one or more notches in a transmission response of the second FSL.

5. The RF system of claim 4, wherein the transmission response of the first FSL and the transmission response of the second FSL are the same.

6. The RF filter system of claim 3, wherein the one or more frequencies of the one or more attenuated RF signals correspond to one or more frequencies of the one or more second RF signals.

7. The RF filter system of claim 2, wherein the first FSL and the second FSL comprise absorptive FSLs.

8. The RF filter system of claim 2, wherein the first FSL and the second FSL comprise ferrite-based FSLs.

9. The RF filter system of claim 2, wherein the first FSL and the second FSL comprise magnetostatic surface wave (MSSW) FSLs.

10. The RF filter system of claim 1, wherein the tuning signal injection circuitry comprises a ninety degree hybrid coupler.

11. The RF filter system of claim 2, wherein the tuning signal cancellation circuitry comprises a ninety degree hybrid coupler.

12. The RF filter system of claim 2, wherein the tuning signal injection circuitry comprises a ninety degree hybrid coupler and the tuning signal cancellation circuitry comprises a ninety degree hybrid coupler.

13. The RF filter system of claim 1, wherein the one or more first RF signals comprises a signal of interest and the one or more second RF signals comprises a signal tuned to a first frequency to cause the system to attenuate any of the one or more first RF signals at the first frequency.

14. The RF filter system of claim 1, wherein the one or more first RF signals comprises a signal of interest and an interfering signal, and the RF filter system is configured to output third RF signals including the signal of interest and an attenuated version of the interfering signal.

15. The RF filter system of claim 2, wherein the tuning signal injection circuitry comprises a first output configured to output one or more third RF signals that are a combination of the first one or more RF signals and the second or more RF signals, where the signals combined based on the second one or more RF signals are phase-shifted by ninety degrees relative to the signals combined based on the first one or more RF signals.

16. The RF filter system of claim 15, wherein the tuning signal injection circuitry comprises a second output configured to output one or more fourth RF signals that are a combination of the second one or more RF signals and the first one or more RF signals, wherein the signals combined based on the first one or more RF signals are phase-shifted by ninety degrees relative to the signals combined based on the second one or more RF signals.

17. The RF filter system of claim 16, wherein
the first FSL receives the one or more third RF signals, attenuates one or more of the one or more third RF signals having one or more frequencies corresponding to one or more notches in a transmission response of the first FSL, and outputs the attenuated one or more of the one or more third RF signals and the remaining RF signals of the one or more third RF signals as one or more fifth RF signals; and
the second FSL receives the one or more fourth RF signals, attenuates one or more of the one or more fourth RF signals having one or more frequencies corresponding to one or more notches in a transmission response of the second FSL, and outputs the attenuated one or more of the one or more fourth RF signals and the remaining RF signals of the one or more fourth RF signals as one or more sixth RF signals.

18. The RF filter system of claim 17, wherein the tuning signal cancellation circuitry receives the one or more fifth RF signals at a first input and the one or more sixth RF signals at a second input.

19. The RF filter system of claim 18, wherein the tuning signal cancellation circuitry outputs one or more seventh RF signals that are a combination of the one or more sixth RF signals and the one or more fifth RF signals, whereby the combination of the one or more sixth RF signals and the one or more fifth RF signals results in cancellation of components of the one or more second RF signals, such that the one or more seventh RF signals do not include the components of the one or more second RF signals.

20. The RF filter system of claim 19, wherein the one or more seventh RF signals comprise only components of the one or more first RF signals.

21. The RF filter system of claim 18, wherein the tuning signal cancellation circuitry outputs one or more eighth RF signals that are a combination of the one or more fifth RF signals and the one or more sixth RF signals, whereby the combination of the one or more fifth RF signals and the one or more sixth RF signals results in cancellation of components of the one or more first RF signals, such that the one or more eighth RF signals do not include the components of the one or more first RF signals.

22. The RF filter system of claim 21, wherein the output of the tuning signal cancellation circuitry is terminated in a load.

23. The RF filter system of claim 2, wherein
the first FSL is coupled to the tuning signal injection circuitry over a first interconnect and is coupled to the tuning signal cancellation circuitry over a second interconnect, and
the second FSL is coupled to the tuning signal injection circuitry over a third interconnect and is coupled to the tuning signal cancellation circuitry over a fourth interconnect.

24. The RF filter system of claim 23, wherein the tuning signal injection circuitry, first FSL, second FSL, tuning signal cancellation circuitry, first interconnect, second interconnect, third interconnect, and fourth interconnect are matched.

25. The RF filter system of claim 23, further comprising one or more phase and gain compensation components to compensate for unmatched components.

26. The RF filter system of claim 1, wherein the one or more second RF signals are generated by one of a signal generator, waveform generator, arbitrary waveform generator, field-programmable gate array (FPGA), software-defined radio (SDR), RF synthesizer, antenna, or voltage-controlled oscillator (VCO).

27. The RF filter system of claim 2, further comprising a third FSL coupled to the first input of the tuning signal injection circuitry.

28. The RF filter system of claim 27, wherein the third FSL is a reflective FSL.

29. The RF filter system of claim 27, wherein the third FSL is a magnetostatic surface wave (MSSW) FSL.

30. The RF filter system of claim 27, wherein an input of the third FSL is coupled to a circulator.

31. The RF filter system of claim 30, wherein the circulator is configured to:
receive one or more RF signals and output the one or more RF signals to the third FSL;
receive one or more of the one or more RF signals reflected from the third FSL; and
output the reflected one or more RF signals.

32. The RF filter system of claim 31, wherein the output reflected one or more RF signals comprises the second one or more RF signals.

33. The RF filter system of claim 31, further comprising an amplifier configured to receive the output reflected one or more RF signals and to send an amplified version of the output reflected one or more RF signals as the second one or more RF signals.

34. The RF filter system of claim 27, wherein the third FSL has a predetermined threshold power level.

35. The RF filter system of claim 31, further comprising a signal-to-noise enhancer configured to receive the output reflected one or more RF signals and to attenuate any of the output reflected one or more RF signals having a power level that is below a predetermined threshold power level of the signal-to-noise enhancer.

36. The RF filter system of claim 35, wherein the third FSL has a first predetermined threshold power level and the predetermined threshold power level of the signal-to-noise enhancer is a second predetermined threshold power level, where the first predetermined threshold power level and the second predetermined threshold power level are the same.

37. The RF filter system of claim 35, wherein the third FSL has a first predetermined threshold power level and the predetermined threshold power level of the signal-to-noise enhancer is a second predetermined threshold power level, where the first predetermined threshold power level and the second predetermined threshold power level are different.

38. The RF filter system of claim 35, further comprising an amplifier configured to receive one or more RF signals output from the signal-to-noise enhancer and to provide an amplified version of the one or more RF signals output from the signal-to-noise enhancer as the one or more second RF signals.

39. The RF filter system of claim 33, wherein the amplifier is a first amplifier, further comprising a second amplifier, the circulator configured to receive the one or more RF signals from the second amplifier.

40. The RF filter system of claim 2, further comprising an RF coupler configured to receive one or more RF signals, wherein the one or more first RF signals and the one or more second RF signals are based on signals output from the RF coupler.

41. The RF filter system of claim 40, wherein a direct path of the RF coupler is coupled to the first input of the tuning signal injection circuitry, and a coupled path of the RF coupler is coupled to the second input of the tuning signal injection circuitry.
